(19) United States
(12) Patent Application Publication
(10) Pub. No.: US 2026/0333977 A1
(43) Pub. Date: Oct. 22, 2026

(54) DISPLAY DEVICE

(71) Applicant: Japan Display Inc., Tokyo (JP)

(72) Inventors: Masanobu IKEDA, Tokyo (JP); Masumi NISHIMURA, Tokyo (JP); Kazutaka NAGAOKA, Tokyo (JP)

(73) Assignee: Japan Display Inc., Tokyo (JP)

(21) Appl. No.: 19/706,268

(22) Filed: Jun. 12, 2026

Related U.S. Application Data
(63) Continuation of application No. PCT/JP2024/040524, filed on Nov. 14, 2024.

(30) Foreign Application Priority Data
Dec. 28, 2023 (JP) 2023-222589

(51) Int. Cl. H10H 29/49; H10H 20/825

(52) U.S. Cl. CPC H10H 29/49; H10H 20/825

(57) ABSTRACT

A display device includes a first substrate, a light-emitting diode arranged on a first surface of the first substrate and including a gallium nitride layer, a first transistor arranged on the light-emitting diode and electrically connected to the light-emitting diode, a second substrate facing the first substrate, a data signal line arranged on the second substrate, a ground signal line arranged on the second substrate, a first conductor arranged on the data signal line and electrically connecting the data signal line and the first transistor, and a second conductor arranged on the ground signal line and electrically connecting the ground wiring and the light-emitting diode.

### CROSS-REFERENCE TO RELATED APPLICATIONS

This application is a Continuation of International Patent Application No. PCT/JP2024/040524, filed on Nov. 14, 2024, which claims the benefit of priority to Japanese Patent Application No. 2023-222589, filed on Dec. 28, 2023, the entire contents of which are incorporated herein by reference.

### FIELD

An embodiment of the present invention relates to a display device including a transistor with an oxide semiconductor and a light-emitting element using gallium nitride.

### BACKGROUND

In recent years, display devices using gallium nitride (GaN) light-emitting elements in a display unit have been known. For example, the light-emitting element is a light-emitting diode (LED) or a micro light-emitting diode (micro-LED). For example, the display device includes a sapphire substrate on which the light-emitting element is formed, and a backplane on which a transistor containing an oxide semiconductor or low-temperature polysilicon is formed, and a method for manufacturing the display device includes electrically connecting the light-emitting element and the transistor by transferring the sapphire substrate to the backplane. The light-emitting elements of the display device manufactured in this manner can conduct a current corresponding to the potential supplied to the transistor. As a result, the light-emitting element emits light, and the display device can display an image on the display unit.

### SUMMARY

A display device according to one embodiment of the present invention includes a first substrate; a light-emitting diode including a gallium nitride layer arranged on a first surface of the first substrate; a first transistor arranged on the light-emitting diode and electrically connected to the light-emitting diode; a second substrate facing the first substrate; a data signal line arranged on the second substrate; a ground wiring arranged on the second substrate; a first conductor arranged on the data signal line and electrically connecting the data signal line to the first transistor; and a second conductor arranged on the ground wiring and electrically connecting the ground wiring to the light-emitting diode.

### BRIEF DESCRIPTION OF DRAWINGS

FIG. 1 is a plan view showing a configuration of a display device according to a first embodiment of the present invention.

FIG. 2 is a circuit diagram showing a circuit configuration of a pixel included in the display device according to the first embodiment of the present invention.

FIG. 3 is a diagram showing a configuration of a connection between a pixel circuit and each wiring included in the display device according to the first embodiment of the present invention.

FIG. 4 is a schematic plan view showing an example of a layout of a pixel according to the first embodiment of the present invention.

FIG. 5 is a cross-sectional view showing a cross-sectional structure along a line A1-A2 of the display device shown in FIG. 1.

FIG. 6 is a flowchart showing an example of a method for manufacturing the display device according to the first embodiment of the present invention.

FIG. 7 is a cross-sectional view showing an example of a cross-sectional structure in a manufacturing process of the display device according to the first embodiment of the present invention.

FIG. 8 is a cross-sectional view showing an example of a cross-sectional structure in a manufacturing process of the display device according to the first embodiment of the present invention.

FIG. 9 is a cross-sectional view showing an example of a cross-sectional structure in a manufacturing process of the display device according to the first embodiment of the present invention.

FIG. 10 is a cross-sectional view showing an example of a cross-sectional structure in a manufacturing process of the display device according to the first embodiment of the present invention.

FIG. 11 is a flowchart showing an example of a method for manufacturing a display device according to the first embodiment of the present invention.

FIG. 12 is a cross-sectional view showing an example of a cross-sectional structure in a manufacturing process of the display device according to the first embodiment of the present invention.

FIG. 13 is a cross-sectional view showing an example of a cross-sectional structure in a manufacturing process of the display device according to the first embodiment of the present invention.

FIG. 14 is a cross-sectional view showing an example of a cross-sectional structure in a manufacturing process of the display device according to the first embodiment of the present invention.

FIG. 15 is a cross-sectional view showing an example of a cross-sectional structure in a manufacturing process of the display device according to the first embodiment of the present invention.

FIG. 16 is a plan view showing an example of a manufacturing process of the display device according to the first embodiment of the present invention.

FIG. 17 is an enlarged view of the plan view shown in FIG. 16.

FIG. 18 is a flowchart showing an example of a method for manufacturing a display device according to the first embodiment of the present invention.

FIG. 19 is a cross-sectional view showing an example of a cross-sectional structure in a manufacturing process of the display device according to the first embodiment of the present invention.

FIG. 20 is a cross-sectional view showing an example of a cross-sectional structure in a manufacturing process of the display device according to the first embodiment of the present invention.

FIG. 21 is a cross-sectional view showing an example of a cross-sectional structure in a manufacturing process of the display device according to the first embodiment of the present invention.

FIG. 22 is a plan view showing an example of a manufacturing process of a display device according to a second embodiment of the present invention.

FIG. 23 is a cross-sectional view showing a cross-sectional structure along a line B1-B2o the display device shown in FIG. 22.

FIG. 24 is a cross-sectional view showing a cross-sectional structure along a line C1-C2 the display device shown in FIG. 22.

FIG. 25 is a flowchart showing an example of a method for manufacturing a display device according to the second embodiment of the present invention.

FIG. 26 is a cross-sectional view showing an example of a cross-sectional structure in a manufacturing process of the display device according to the second embodiment of the present invention.

FIG. 27 is a cross-sectional view showing an example of a cross-sectional structure in a manufacturing process of the display device according to the second embodiment of the present invention.

FIG. 28 is a cross-sectional view showing an example of a cross-sectional structure in a manufacturing process of the display device according to the second embodiment of the present invention.

FIG. 29 is a cross-sectional view showing an example of a cross-sectional structure in a manufacturing process of the display device according to the second embodiment of the present invention.

FIG. 30 is a cross-sectional view showing an example of a cross-sectional structure in a manufacturing process of the display device according to the second embodiment of the present invention.

FIG. 31 is a plan view showing a configuration of a protection circuit according to the second embodiment of the present invention.

### DESCRIPTION OF EMBODIMENTS

Hereinafter, embodiments of the present invention will be described with reference to the drawings and the like. However, the present invention can be implemented in many different ways and is not limited to the description of the embodiments exemplified below. For clarity of explanation, the drawings may be schematically represented in terms of width, thickness, shape, and the like of respective portions as compared with actual embodiments, but the drawings are merely examples, and do not limit the interpretation of the present invention. Furthermore, in the present specification and drawings, elements similar to those previously described with respect to the preceding figures may be denoted by the same reference signs (or numbers followed by a letter, such as a, b), and detailed descriptions may be omitted as appropriate. In addition, the terms “first” and “second” appended to each element are convenient labels used to distinguish each element and have no further meaning unless specifically explained.

In the case where a member or region is to be “on (or under)” another member or region in the present specification, unless otherwise specified, this includes not only the case where it is directly above (or below) the other member or region, but also the case where it is above (or below) the other member or region, that is, it also includes the case where another component is included above (below) the other member or region.

In the present specification, a direction D1 intersects a direction D2, and a direction D3 intersects the direction D1 and the direction D2 (a D1-D2 plane). For example, the direction D1, the direction D2, and the direction D3 correspond to a direction X (direction x), a direction Y (direction y), and a direction Z (direction z). In addition, even if the direction D3 deviates from perpendicular to the directions D1 and D2 within a margin of error, the direction D3 is still considered perpendicular to the directions D1 and D2. In this case, for example, it is referred to as approximately perpendicular.

In the present specification, when the terms same and coincident are used, the same and coincident may include tolerances within the design range.

### 1. First Embodiment

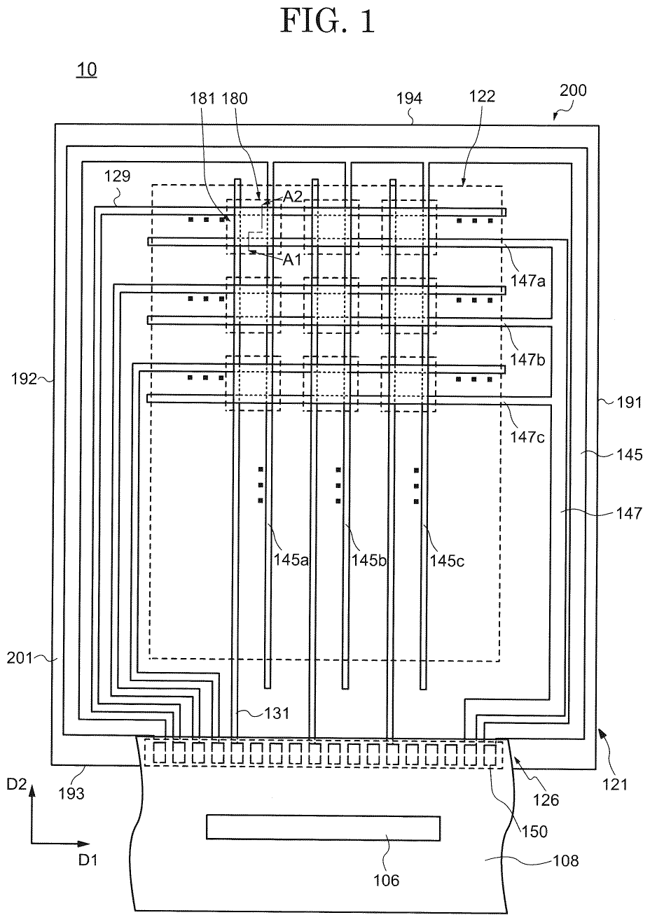

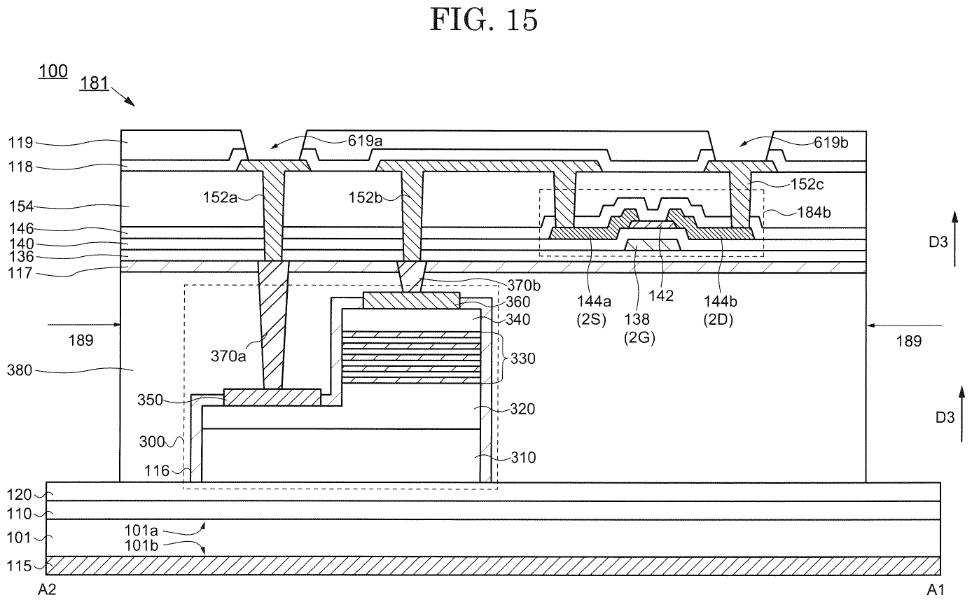

A configuration of a display device 10 will be described with reference to FIG. 1 to FIG. 21.

### 1-1. Overview of Display Device 10

An overview of the display device 10 will be described with reference to FIG. 1. FIG. 1 is a schematic plan view showing the configuration of the display device 10.

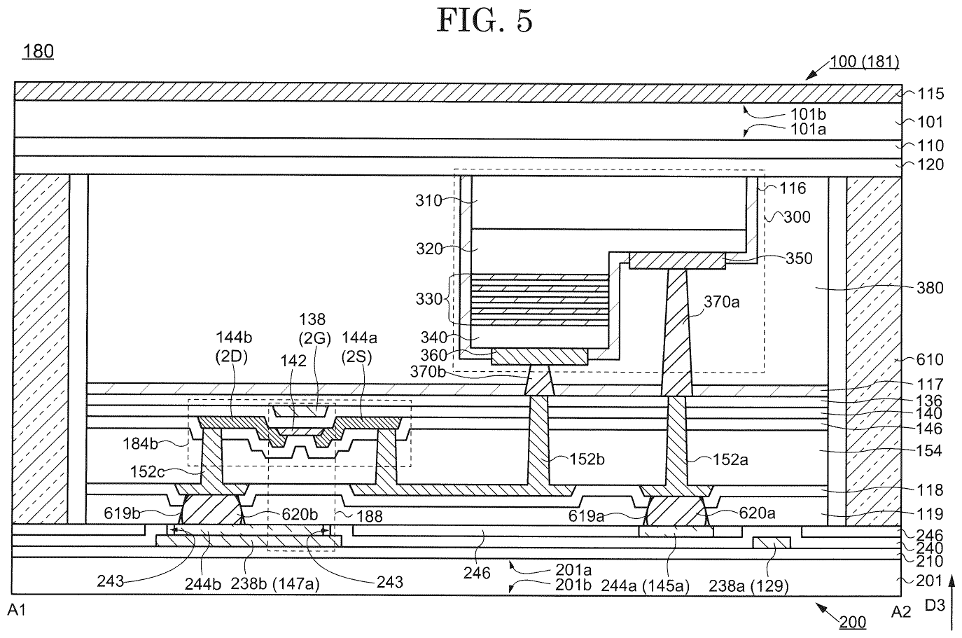

The display device 10 includes at least a first substrate 101 (see FIG. 5), a second substrate 201, a flexible printed circuit board (FPC) 108, and a driver IC 106. In addition, the display device 10 includes at least a display region 122 on a first surface 201a (see FIG. 5) of the second substrate 201 (see FIG. 5) and a peripheral region 121 surrounding the display region 122. Although details will be described later, an array substrate 100 (see FIG. 5) includes the first substrate 101, and a backplane 200 (see FIG. 5) includes the second substrate 201.

The second substrate 201 includes a first side 191, a second side 192 facing the first side, a third side 193, and a fourth side 194 facing the third side. The display region 122 and the peripheral region 121 are surrounded by the first side 191, the second side 192 facing the first side, the third side 193, and the fourth side 194 facing the third side 193 in a plan view.

A plurality of pixels 180 is arranged in the display region 122. The display region 122 Is a region that overlaps the plurality of pixels 180 in a plan view. The plurality of pixels 180 is arranged in a matrix in the first direction D1 and the second direction D2. The arrangement of the plurality of pixels 180 is not limited to a matrix. For example, the plurality of pixels 180 may be arranged in a staggered pattern. Although details will be described later, the pixel 180 includes a pixel IC chip 181.

The peripheral region 121 includes a plurality of scanning signal lines 129, a plurality of data signal lines 131, a ground wiring 145, a driving potential line 147, and a terminal region 126. The peripheral region 121 is a region that overlaps the plurality of scanning signal lines 129, the plurality of data signal lines 131, the ground wiring 145, the driving potential line 147, and the terminal region 126 in a plan view. The plurality of scanning signal lines 129, the plurality of data signal lines 131, the ground wiring 145, and the driving potential line 147 are electrically connected to corresponding pixels 180 among the plurality of pixels 180.

The terminal region 126 is a region on the third side 193 side. A plurality of terminals 150 is arranged in the terminal region 126. The plurality of terminals 150 is electrically connected to the FPC 108, the plurality of scanning signal lines 129, the plurality of data signal lines 131, the ground wiring 145, and the driving potential line 147. The terminal region 126 is a region that, in a plan view, overlaps the plurality of terminals 150 for connecting the plurality of scanning signal lines 129, the plurality of data signal lines 131, the ground wiring 145, and the driving potential line 147 to the FPC 108, the driver IC 106, and an external circuit (not shown). In addition, the plurality of terminals 150 is included in the second substrate 201 and overlaps the FPC 108.

For example, the driver IC 106 is arranged on the FPC 108. The driver IC 106 supplies a control signal for driving the plurality of pixels 180 to the plurality of pixels 180 via the FPC 108, the scanning signal line 129, the data signal line 131, the ground wiring 145, and the driving potential line 147.

The ground wiring 145 is arranged to surround the display region 122. The ground wiring 145 includes a wiring electrically connected to the terminal 150 on the first side 191 side and extending in the direction D1 along the third side 193, a wiring extending in the direction D2 along the first side 191, a wiring extending in the direction D1 along the fourth side 194, a wiring extending in the direction D2 along the second side 192, and a wiring electrically connected to the terminal 150 on the second side 192 side and extending in the direction D1 along the third side 193. Furthermore, the ground wiring 145 includes ground wirings 145a, 145b, and 145c electrically connected to the wiring extending in the direction D1 along the fourth side 194 and branched from the fourth side 194 side toward the third side 193 side along the direction D2. For example, a constant potential such as a ground voltage, an earth voltage, a voltage VSS, or 0 V is supplied to the ground wiring 145. These voltages (potentials) are reference potentials for each signal and may be called reference voltages (potentials).

The driving potential line 147 includes the wiring electrically connected to the terminal 150 on the first side 191 side and extending in the direction D1 along the third side 193, and the wiring extending in the direction D2 along the first side 191. In addition, the driving potential line 147 includes driving potential lines 147a, 147b, and 147c electrically connected to the wiring extending in the direction D2 along the first side 191 and branched from the first side 191 side toward the second side 192 side along the direction D1. The driving potential lines 147a, 147b, and 147c are electrically connected to a plurality of pixel IC chips 181 arranged along the direction D1, respectively. For example, a constant potential higher than the potential supplied to the ground wiring 145 is supplied to the driving potential line 147. The constant potential higher than the potential supplied to the ground wiring 145 is, for example, a potential such as a voltage VDD or 30 V. Similar to the ground wiring 145, the driving potential line 147 may be arranged to surround the display region 122.

The ground wiring 145 including the configuration described above can uniformly supply a constant potential such as a ground voltage to the plurality of pixel IC chips 181. In addition, the driving potential line 147 including the configuration described above can uniformly supply a constant potential such as a voltage VDD to the plurality of pixel IC chips 181. As a result, the display device 10 can display an image without unevenness in the display region 122.

### 1-2. Configuration of Pixel 180

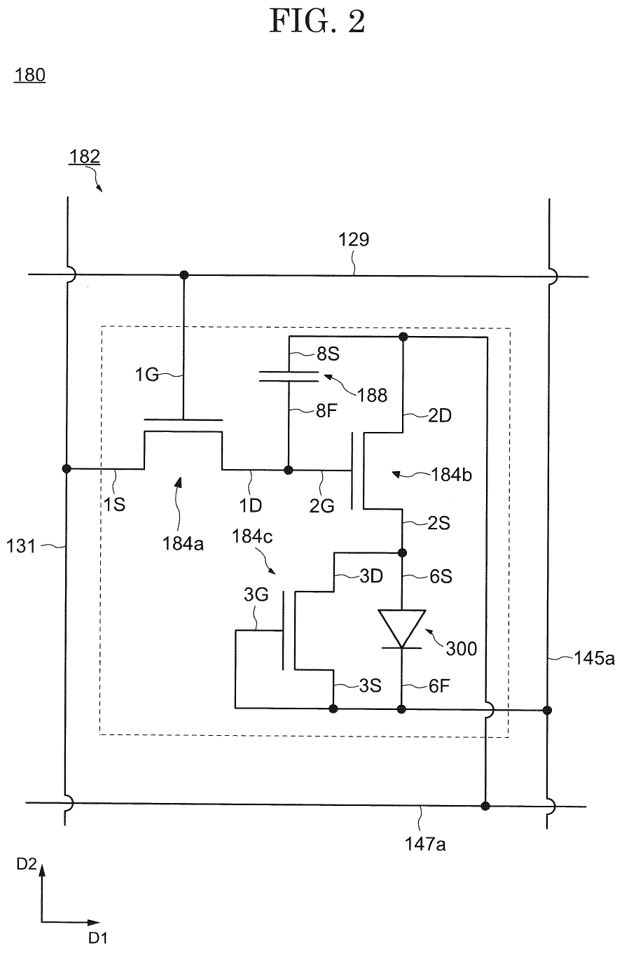

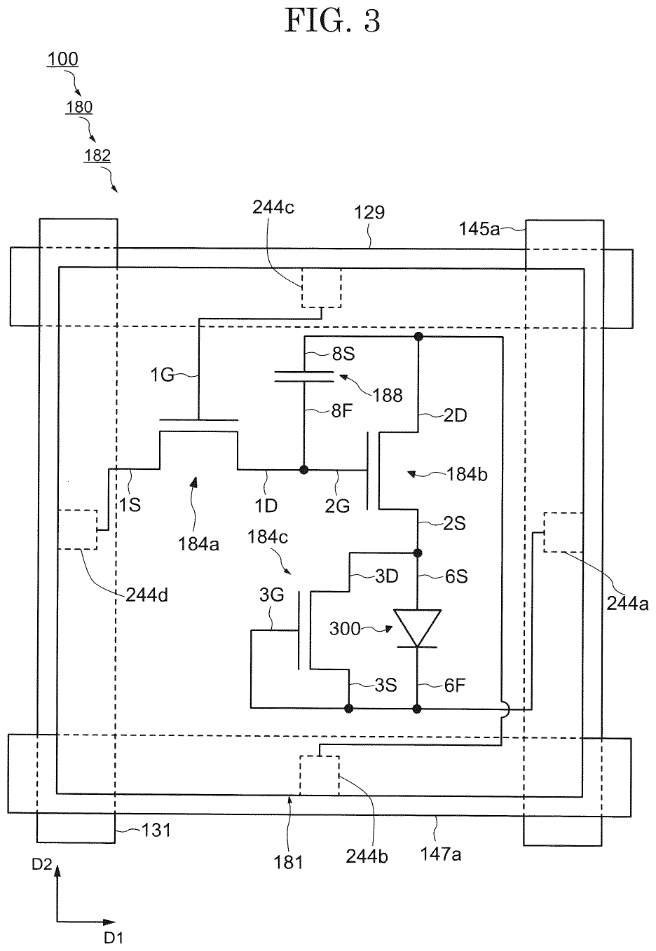

A configuration of the pixel 180 will be described with reference to FIG. 2 and FIG. 3. FIG. 2 is a schematic circuit diagram showing a configuration of a pixel circuit 182 of the pixel 180 of the display device 10. FIG. 3 is a schematic diagram showing electrical connections between the pixel IC chip 181 including the pixel circuit 182 and the scanning signal line 129, the data signal line 131, the ground wiring 145, and the driving potential line 147. Configurations that are the same as or similar to those in FIG. 1 will be described as necessary.

The pixel 180 includes the pixel IC chip 181 electrically connected to the scanning signal line 129, the data signal line 131, the ground wiring 145, and the driving potential line 147.

The pixel IC chip 181 includes a first transistor 184a, a second transistor 184b, a third transistor 184c, a light-emitting diode 300, and a capacitance element 188. In addition, the pixel IC chip 181 includes first connecting conductive layers 244a, 244b, 244c, and 244d. For example, the first connecting conductive layers 244a, 244b, 244c, and 244d connect corresponding electrodes and wirings using solder or an anisotropic conductive film (ACF). For example, the first connecting conductive layer 244a is arranged between and connects a gate electrode 3G, a source electrode 3S, and a cathode 6F to the ground wiring 145a, the first connecting conductive layer 244b is arranged between and connects a drain electrode 2D and a second electrode 8S to the driving potential line 147a, the first connecting conductive layer 244c is arranged between and connects a gate electrode 1G to the scanning signal line 129, and the first connecting conductive layer 244d is arranged between and connects a source electrode 1S to the data signal line 131.

In the description of the first connecting conductive layer included in the pixel 180, when the first connecting conductive layers are not distinguished, the first connecting conductive layer is described as a first connecting conductive layer 244, and when the first connecting conductive layers are distinguished, the first connecting conductive layers are assigned individual reference signs such as the first connecting conductive layers 244a to 244d.

The first transistor 184a can function as a selecting transistor. The conduction state of the first transistor 184a is controlled by the scanning signal line 129. The first transistor 184a includes the gate electrode 1G, the source electrode 1S, and a drain electrode 1D. The source electrode 1S is electrically connected to the data signal line 131, the drain electrode 1D is electrically connected to a gate electrode 2G of the second transistor 184b and a first electrode 8F of the capacitance element 188, and the gate electrode 1G is electrically connected to the scanning signal line 129.

The second transistor 184b can function as a driving transistor. The second transistor 184b

controls the brightness of the light-emitting diode 300. The conduction state of the second transistor 184b is controlled by the first transistor 184a. The second transistor 184b includes the gate electrode 2G, a source electrode 2S, and the drain electrode 2D. The source electrode 2S is electrically connected to a drain electrode 3D of the third transistor 184c and an anode 6S of the light-emitting diode 300, the drain electrode 2D is electrically connected to the driving potential line 147 and the second electrode 8S of the capacitance element 188, and the gate electrode 2G is electrically connected to the drain electrode 1D and the first electrode 8F.

The third transistor 184c can function as a protection circuit for the light-emitting diode 300. third transistor 184c includes the gate electrode 3G, the source electrode 3S, and the drain electrode 3D. The third transistor 184c is connected in parallel to the light-emitting diode 300. More specifically, the source electrode 3S is electrically connected to the gate electrode 3G, the cathode 6F of the light-emitting diode 300 and the ground wiring 145, and the drain electrode 3D is electrically connected to the anode 6S and the source electrode 2S. The gate electrode 3G is electrically connected to the source electrode 3S, and the third transistor 184c is a so-called diode including a diode connection. The conduction state of the third transistor 184c is controlled by the potential difference between the potential supplied to the drain electrode 3D and the potential supplied to the source electrode 3S. Since the source electrode 3S is electrically connected to the ground wiring 145, the potential supplied to the drain electrode 3D is basically equal to or higher than the potential supplied to the ground wiring 145. When the potential supplied to the drain electrode 3D is lower than the potential supplied to the ground wiring 145, the third transistor 184c becomes conductive and functions as a protection circuit. That is, when an overvoltage is applied between the anode 6S and the cathode 6F of the light-emitting diode 300, the pixel 180 (the pixel circuit 182) can cause the current flowing through the light-emitting diode 300 to flow to the ground wiring 145 via the third transistor 184c. As a result, the third transistor 184c can suppress the application of overvoltage and the supply of overcurrent to the light-emitting diode 300.

In the description of the transistors included in the pixel 180, when the transistors are not distinguished, the transistor is described as the transistor 184, and when the transistors are distinguished, the transistors are described as the first transistor 184a, the second transistor 184b, and the third transistor 184c.

The light-emitting diode 300 includes the cathode (n-type electrode) 6F and the anode (p-type electrode) 6S.

The capacitance element 188 includes the first electrode 8F and the second electrode 8S. For example, the capacitance element 188 can hold a charge corresponding to a potential corresponding to an image displayed by the pixel 180. In addition, for example, the capacitance element 188 can hold a charge corresponding to a threshold voltage of the second transistor 184b and correct the threshold voltage of the second transistor 184b. As a result, the second transistor 184b can supply a stable current corresponding to the potential corresponding to the image to the light-emitting diode 300.

Arbitrary control signals are supplied from the driver IC 106 and the external circuit to the pixel circuit 182 of the plurality of pixels 180 of the display device 10, and the display device 10 can display an image in the display region 122.

Furthermore, in the present specification and drawings, for convenience of explanation, the function as a source and the function as a drain of each electrode may be interchanged depending on the potential supplied to the source electrode and the drain electrode of each transistor.

### 1-3. Example of Layout

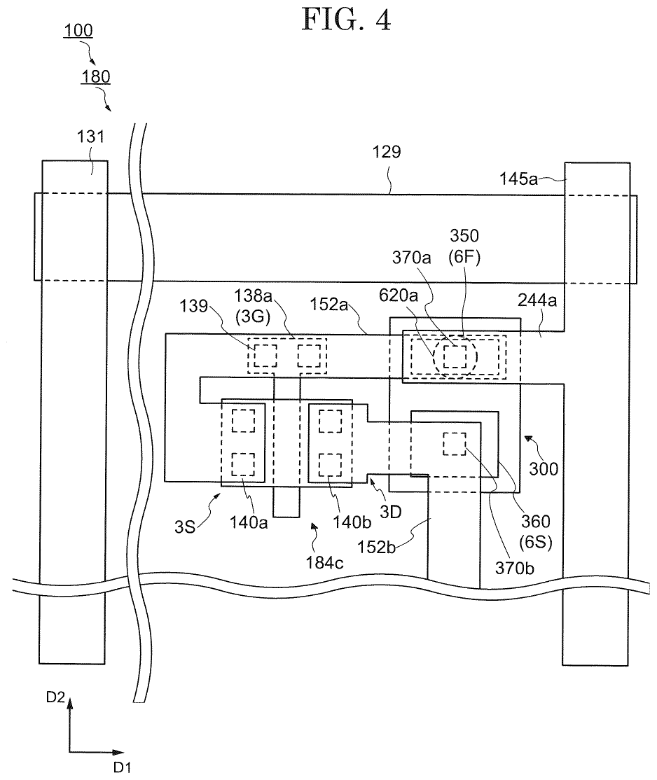

An example of the layout of the third transistor 184c and the light-emitting diode 300 will be described with reference to FIG. 4. FIG. 4 is a schematic plan view showing an example of a layout of the third transistor 184c and the light-emitting diode 300. Configurations that are the same as or similar to those in FIG. 1 to FIG. 3 will be described as necessary.

An n-type electrode 350 (the cathode 6F) of the light-emitting diode 300 is connected to a second connecting conductive layer 370a, a conductive layer 152a, and a conductive connecting member 620a, and is connected to the first connecting conductive layer 244a and the ground wiring 145a via the second connecting conductive layer 370a, the conductive layer 152a, and the conductive connecting member 620a. The n-type electrode 350 (the cathode 6F) is connected to a gate electrode 138a (the gate electrode 3G) exposed from an opening 139 and the source electrode 3S exposed from an opening 140a via the second connecting conductive layer 370a and the conductive layer 152a. A p-type electrode 360 (the anode 6S) of the light-emitting diode 300 is connected to a second connecting conductive layer 370b and a conductive layer 152b, and is connected to the drain electrode 3D exposed from an opening 140b via the second connecting conductive layer 370b and the conductive layer 152b.

That is, the third transistor 184c and the light-emitting diode 300 are provided on the same IC chip (the pixel IC chip 181). In addition, as described in “1-2”, the third transistor 184c functions as the protection circuit for the light-emitting diode 300. The display device 10 can have a configuration in which the light-emitting diode 300 and the third transistor 184c that protects the light-emitting diode 300 are integrally formed, rather than separately providing the light-emitting diode 300 and the third transistor 184c that protects the light-emitting diode 300. As a result, the electrical connection between the light-emitting diode 300 and the third transistor 184c can be stabilized compared to separately providing the light-emitting diode 300 and the third transistor 184c that protects the light-emitting diode 300. Therefore, the display device 10 can suppress variations in contact resistance between the light-emitting diode 300 and the third transistor 184c, and can stabilize the electrical characteristics of the light-emitting diode 300 and the third transistor 184c, thereby suppressing the deterioration of the light emission characteristics, temperature characteristics, and the like of the pixel 180.

### 1-4. Example of Cross Section of Pixel 180

An example of a cross section of the pixel 180 will be described with reference to FIG. 5. 5 is a cross-sectional view showing an example of a cross-sectional structure of the pixel 180 of the display device 10. Specifically, FIG. 5 is a cross-sectional view showing an example of a cross-sectional structure of the pixel 180 cut along a line A1-A2 shown in FIG. 1. Configurations that are the same as or similar to those in FIG. 1 to FIG. 4 will be described as necessary.

The display device 10 includes the array substrate 100 and the backplane 200. The array substrate 100 includes the first substrate 101, an underlayer 110, a buffer layer 120, the light-emitting diode 300, an insulating layer 380, an insulating layer 117, an insulating layer 136, the second transistor 184b, an insulating layer 154, the conductive layers 152a, 152b, and 152c, an insulating layer 118, an insulating layer 119, openings 619a and 619b, and a color conversion layer 115. The backplane 200 includes the second substrate 201, an underlayer 210, the plurality of terminals 150 (see FIG. 1), conductive layers 238a and 238b, the first connecting conductive layers 244a and 244b, an insulating layer 240, and an insulating layer 246.

The first substrate 101 is a substrate (first support substrate) that supports the transistor 184 and the light-emitting diode 300. The first substrate 101 includes a first surface 101a and a second surface 101b facing the first surface 101a. The buffer layer 120, the light-emitting diode 300, the insulating layer 380, the insulating layer 117, the insulating layer 136, the second transistor 184b, the insulating layer 154, the conductive layers 152a, 152b, and 152c, the insulating layer 118, the insulating layer 119, and the openings 619a and 619b are arranged on the first surface 101a. In addition, the color conversion layer 115 is arranged on the second surface 101b.

The underlayer 110 is arranged on the first substrate 101. The buffer layer 120 is arranged on the underlayer 110.

The light-emitting diode 300 is arranged on the buffer layer 120. The light-emitting diode 300 includes a gallium nitride layer 310, an n-type semiconductor layer 320, a light-emitting layer 330, a p-type semiconductor layer 340, the n-type electrode 350, and the p-type electrode 360.

The gallium nitride layer 310 is arranged on the buffer layer 120. The n-type semiconductor layer 320 is arranged on the gallium nitride layer 310. The light-emitting layer 330 is arranged on the n-type semiconductor layer 320. The p-type semiconductor layer 340 is arranged on the light-emitting layer 330. The n-type electrode 350 is arranged on the n-type semiconductor layer 320. The p-type electrode 360 is arranged on the p-type semiconductor layer 340.

An insulating layer 116 is arranged to cover the light-emitting diode 300. Specifically, the insulating layer 116 is arranged on a part of the surface of the buffer layer 120, the side surface of the gallium nitride layer 310, the side surface and a part of the surface of the n-type semiconductor layer 320, the side surface of the light-emitting layer 330, and the side surface and a part of the surface of the p-type semiconductor layer 340.

In addition, the light-emitting diode 300 is a so-called micro-LED or mini-LED. However, the light-emitting diode 300 is not limited to the LED shown in the display device 10. The length of one side of the micro-LED is 100 μm or less, and the length of one side of the mini-LED is longer than 100 μm.

The insulating layer 380 is arranged to cover a part of the surface of the buffer layer 120, the light-emitting diode 300, and the insulating layer 116. The insulating layer 117 is arranged on the insulating layer 380. The insulating layer 380 may be referred to as a first planarization film.

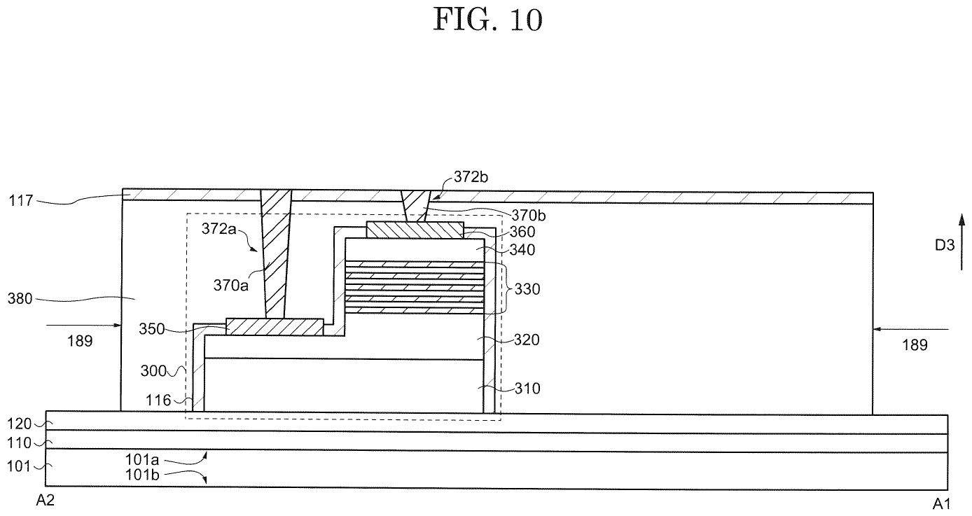

The second connecting conductive layer 370a is in contact with an opening 372a (see FIG. 10) and the n-type electrode 350, and is electrically connected to the n-type electrode 350 via the opening 372a. The second connecting conductive layer 370b is in contact with an opening 372b (see FIG. 10) and the p-type electrode 360, and is electrically connected to the p-type electrode 360 via the opening 372b. In addition, since the openings 372a and 372b are formed in the insulating layers 117 and 380, the second connecting conductive layer 370a is in contact with the insulating layers 117 and 380 serving as the sidewalls of the opening 372a, and the second connecting conductive layer 370b is in contact with the insulating layers 117 and 380 serving as the sidewalls of the opening 372b.

The insulating layer 136 is arranged on the insulating layer 117. In addition, the insulating layer 136 is arranged on the surfaces of the second connecting conductive layers 370a and 370b. For example, the insulating layer 136 is an underlayer.

The transistor 184 is arranged on the insulating layer 136. The transistor 184 includes a conductive layer 138, a gate insulating layer 140, an oxide semiconductor layer 142, a source electrode 144a, and a drain electrode 144b. For example, the transistor 184 shown in FIG. 5 is the second transistor 184b.

The conductive layer 138 is arranged on the insulating layer 136. The conductive layer 138 functions as a gate electrode. For example, the conductive layer 138 shown in FIG. 5 is the gate electrode 2G.

The gate insulating layer 140 is arranged on the conductive layer 138 and on the surface of the insulating layer 136.

The oxide semiconductor layer 142 is arranged on the gate insulating layer 140. The oxide semiconductor layer 142 is used as a channel of the transistor 184.

The source electrode 144a and the drain electrode 144b are arranged on the oxide semiconductor layer 142 and on the gate insulating layer 140, spaced apart from each other. The source electrode 144a and the drain electrode 144b are electrically connected to the oxide semiconductor layer 142. The source electrode 144a and the drain electrode 144b of the display device 10 are connected in direct contact with the oxide semiconductor layer 142. Furthermore, in the description of the source electrode, drain electrode, and wiring formed in the same layer as the source electrode and drain electrode included in the pixel 180, when the source electrode, drain electrode, and wiring are not distinguished, the source electrode, drain electrode, and wiring are described as the conductive layer 144, and when the source electrode, drain electrode, and wiring are distinguished, the source electrode, drain electrode, and wiring are assigned individual reference signs such as the source electrode 144a, the drain electrode 144b, and the like.

An insulating layer 146 is arranged on the source electrode 144a and the drain electrode 144b, on a part of the surface of the oxide semiconductor layer 142, and on a part of the gate insulating layer 140. That is, the insulating layer 146 is arranged to cover the transistor 184. The insulating layer 154 is arranged on the insulating layer 146. That is, the insulating layer 154 is arranged to cover the transistor 184.

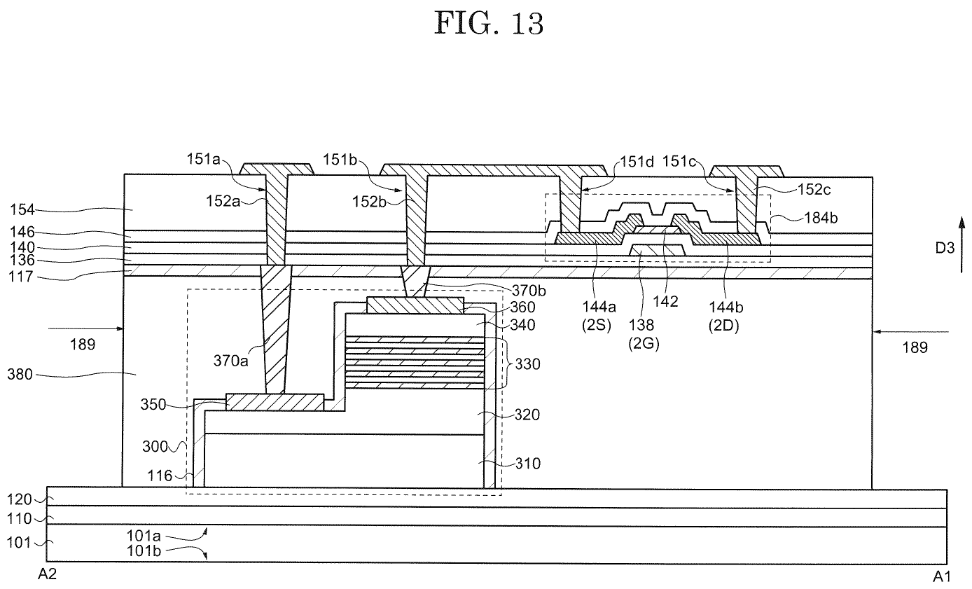

The conductive layer 152a is in contact with an opening 151a (see FIG. 13) and the second connecting conductive layer 370a, and is electrically connected to the second connecting conductive layer 370a via the opening 151a. The conductive layer 152b is in contact with an opening 151b (see FIG. 13) and the second connecting conductive layer 370b, and is electrically connected to the second connecting conductive layer 370b via the opening 151b. In addition, the conductive layer 152b is in contact with an opening 151d (see FIG. 13) and the source electrode 144a, and is electrically connected to the source electrode 144a via the opening 151d. The conductive layer 152c is in contact with an opening 151c (see FIG. 13) and the drain electrode 144b, and is electrically connected to the drain electrode 144b via the opening 151c. In addition, since the openings 151a and 151b are formed in the insulating layer 136, the gate insulating layer 140, and the insulating layers 146 and 154, the conductive layers 152a and 152b are in contact with the insulating layer 136, the gate insulating layer 140, and the insulating layers 146 and 154 serving as the sidewalls of the openings 151a and 151b. Since the openings 151c and 151d are formed in the insulating layers 146 and 154, the conductive layers 152b and 152c are in contact with the insulating layers 146 and 154 serving as the sidewalls of the openings 151c and 151d.

The insulating layer 118 is arranged on the insulating layer 154 and the conductive layers 152a, 152b, and 152c. That is, the insulating layer 118 is arranged to cover the conductive layers 152a, 152b, and 152c. The insulating layer 119 is arranged on the insulating layer 118.

The openings 619a and 619b are formed in the insulating layers 118 and 119. The conductive connecting member 620a is arranged to be in contact with the opening 619a and the conductive layer 152a, and the conductive connecting member 620a is electrically connected to the conductive layer 152a. A conductive connecting member 620b is arranged to be in contact with the opening 619b and the conductive layer 152c, and the conductive connecting member 620b is electrically connected to the conductive layer 152c. The conductive connecting members 620a and 620b may be referred to as conductors (a first conductor and a second conductor).

An adhesive resin material 610 is arranged on the buffer layer 120. The adhesive resin material 610 is formed to surround at least a part of the periphery of the light-emitting diode 300 and the transistor 184 in a cross-sectional view.

The second substrate 201 is a substrate (second support substrate) that supports the plurality of terminals 150, the plurality of scanning signal lines 129, the plurality of data signal lines 131, the ground wiring 145, and the driving potential line 147. The second substrate 201 includes the first surface 201a and a second surface 201b facing the first surface 201a. The underlayer 210, the conductive layers 238a and 238b, the first connecting conductive layers 244a and 244b, the insulating layer 240, and the insulating layer 246 are arranged on the first surface 201a.

The underlayer 210 is arranged on the first substrate 201. The underlayer 210 can prevent the diffusion of impurities from the second substrate 201 or from the outside (for example, moisture or sodium (Na)).

The conductive layers 238a and 238b are arranged on the underlayer 210. The conductive layer 238a functions as the scanning signal line 129. The conductive layer 238b functions as the driving potential line 147a.

The insulating layer 240 is arranged on the conductive layers 238a and 238b. That is, the insulating layer 240 is arranged to cover the plurality of scanning signal lines 129 and the driving potential line 147a. In addition, an opening 243 is formed in the insulating layer 240.

The first connecting conductive layer 244a is arranged on the insulating layer 240. In addition, the first connecting conductive layer 244b is arranged on the conductive layer 238b in the opening 243 of the insulating layer 240, and is electrically connected to the conductive layer 238b. The f irst connecting conductive layers 244a and 244b are formed on different layers in the same process. For example, the first connecting conductive layer 244a extends in the second direction D2 and branches and extends in the first direction D1 as shown in FIG. 4. Although not shown, the first connecting conductive layer 244a is arranged to overlap the insulating layer 240. For example, as shown in FIG. 3, the first connecting conductive layer 244b extends in the first direction D1 and the second direction D2. The first connecting conductive layer 244b may be arranged to overlap the insulating layer 240.

The insulating layer 246 is arranged on the insulating layer 240 and the first connecting conductive layers 244a and 244b. Although details will be described later, the insulating layer 246 is polished and planarized using chemical mechanical polishing (CMP). As a result, the insulating layer 246 is removed from above the first connecting conductive layers 244a and 244b, and a part of the insulating layer 240 and the first connecting conductive layers 244a and 244b are exposed on the surface of the backplane.

For example, the plurality of terminals 150 is formed using the conductive layer 238 and the first connecting conductive layer 244. In addition, the insulating layer 240 on the first connecting conductive layer 244 is opened, the insulating layer 246 on the first connecting conductive layer 244 is polished using CMP, and the first connecting conductive layer 244, whose surface is exposed, is electrically connected to the FPC 300.

The first surface 101a of the array substrate 100 faces the first surface 201a of the backplane 200, and the array substrate 100 is bonded to the backplane 200. Specifically, the array substrate 100 and the backplane 200 are bonded together by the adhesive resin material 610. As a result, the array substrate 100 is electrically connected to the backplane 200 by the conductive connecting members 620a and 620b. Specifically, the conductive layer 152a of the array substrate 100 is electrically connected to the first connecting conductive layer 244a of the backplane 200 via the conductive connecting member 620a, and the conductive layer 152c of the array substrate 100 is electrically connected to the first connecting conductive layer 244b of the backplane 200 via the conductive connecting member 620b. For example, in this case, the conductive layer 238b and the first connecting conductive layer 244b may overlap the second transistor 184b. The conductive layer 238b (the first connecting conductive layer 244b) and the oxide semiconductor layer 142 can form the capacitance element 188 via the insulating layers 119, 118, 154, and 146.

The light-emitting diode 300 of the display device 10 and the plurality of transistors 184 for driving the light-emitting diode 300 can be formed on the same first substrate 101. The light-emitting diode 300 and the second transistor 184b for driving the light-emitting diode 300 are electrically connected on the same first substrate 101. As a result, the display device 10 is formed by transferring the pixel IC chip 181 including the light-emitting diode and the transistor for driving the light-emitting diode to the backplane. That is, by using a stable array process for the driving transistor and an LED connection portion having a small contact area within the pixel IC chip, and using a transfer process for the connection portion between the backplane and the pixel IC chip having a large contact area, the contact resistance value between the light-emitting diode and the transistor can be stabilized. Therefore, since the current supplied to the light-emitting diode 300 by the second transistor 184b is stabilized, the display device 10 can suppress deterioration in the light emission and temperature characteristics of the pixel 180.

### 1-5. One Example of Method for Manufacturing Display Device 10

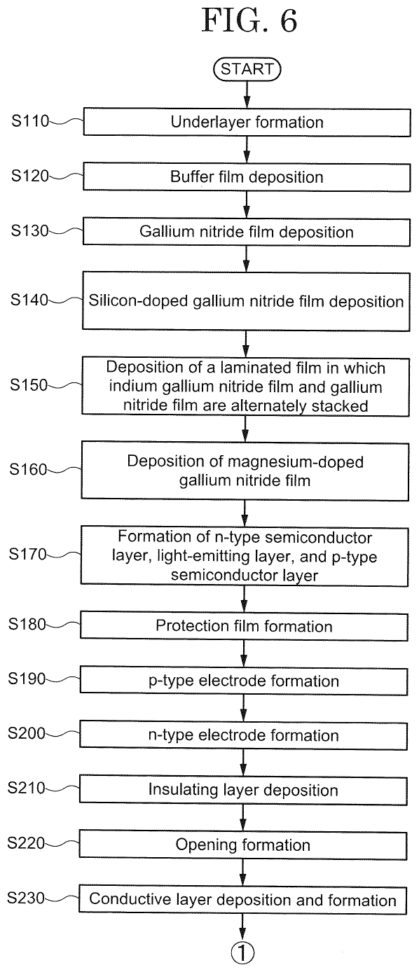

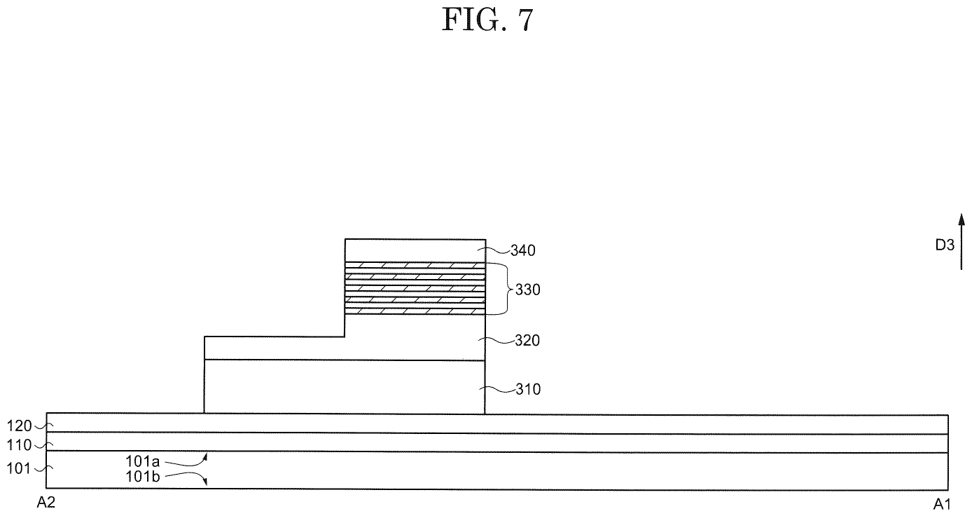

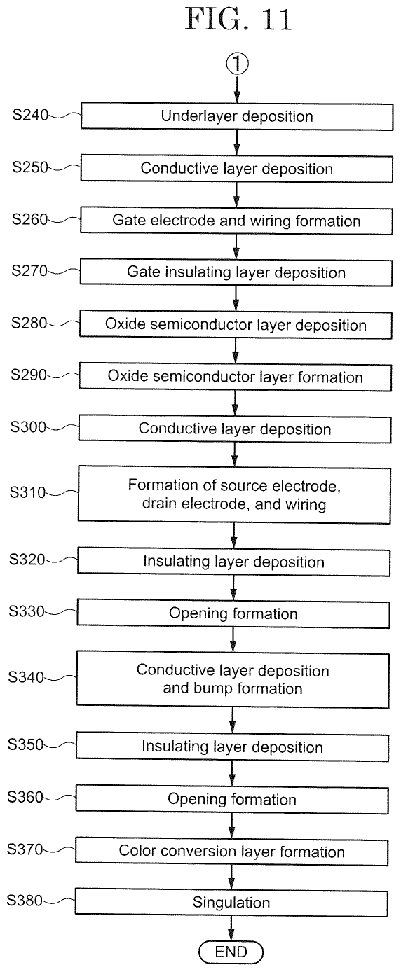

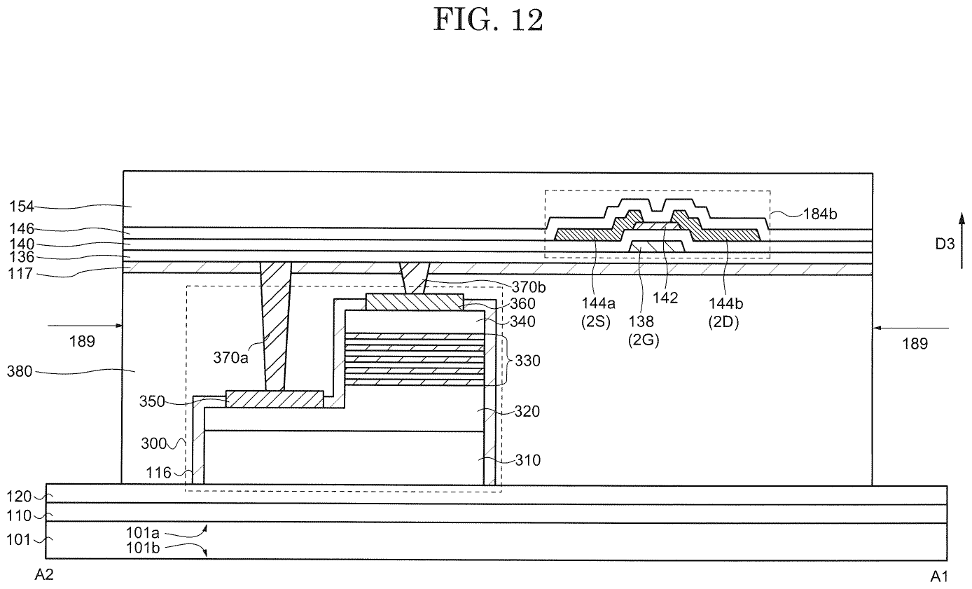

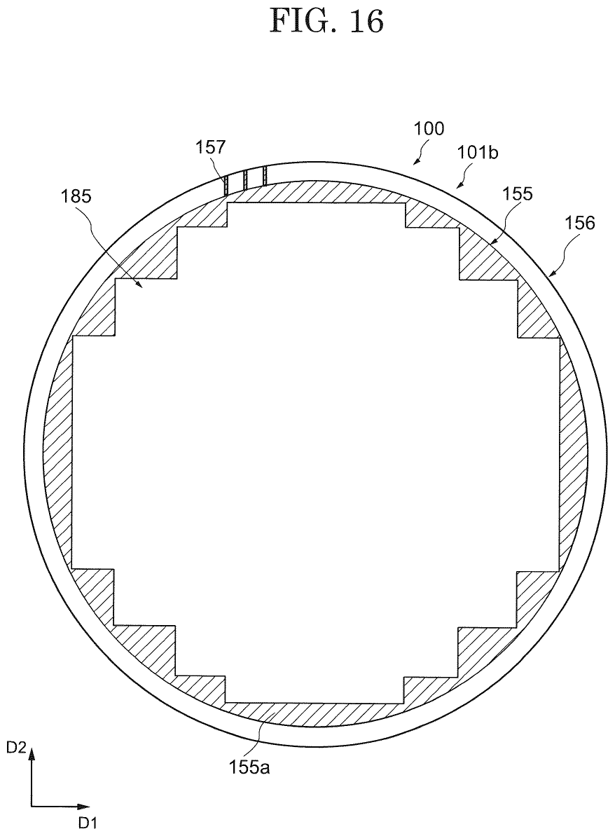

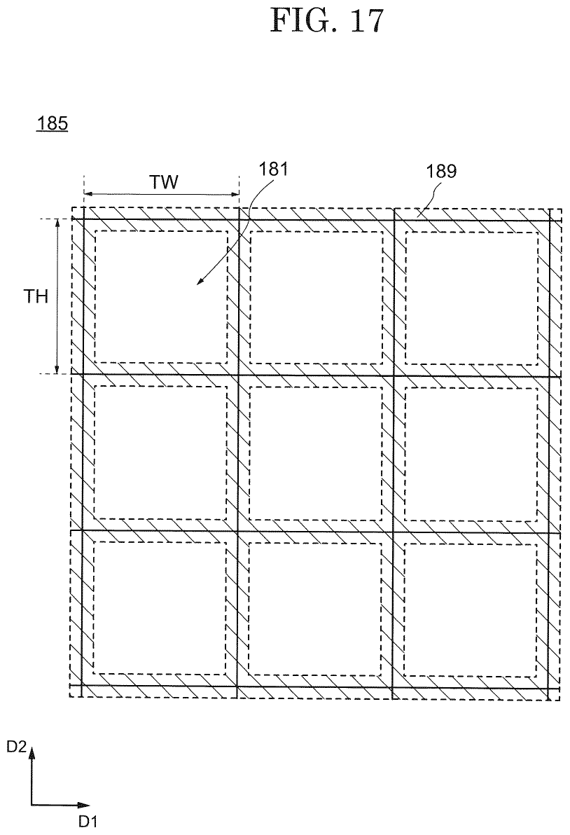

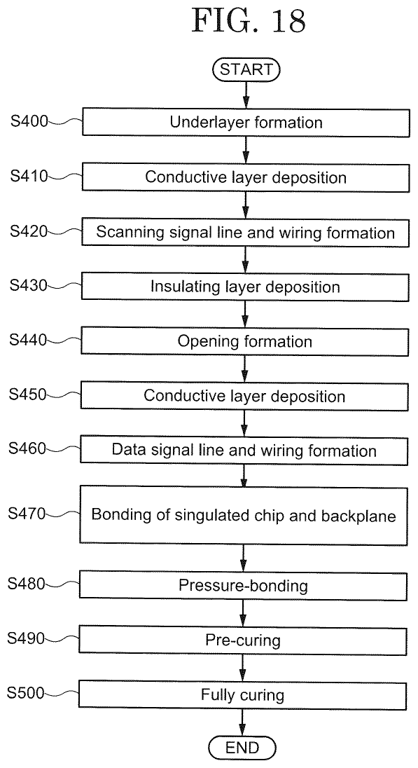

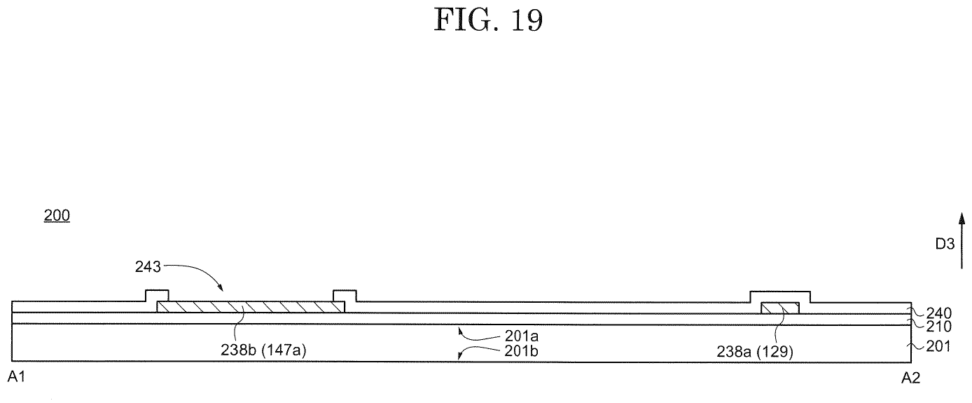

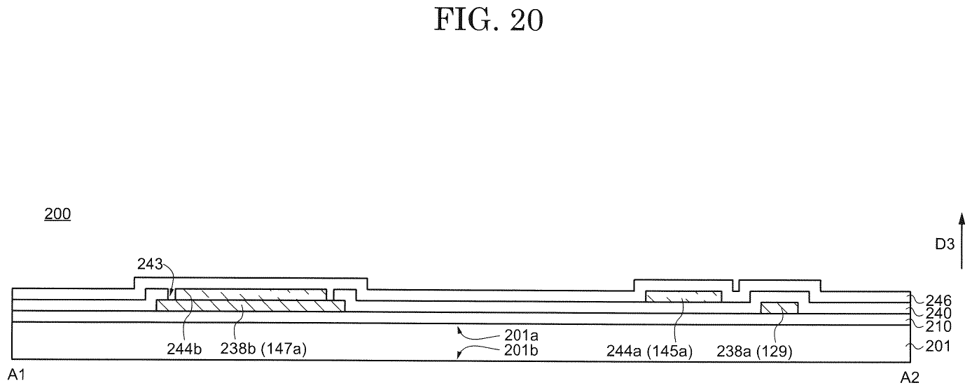

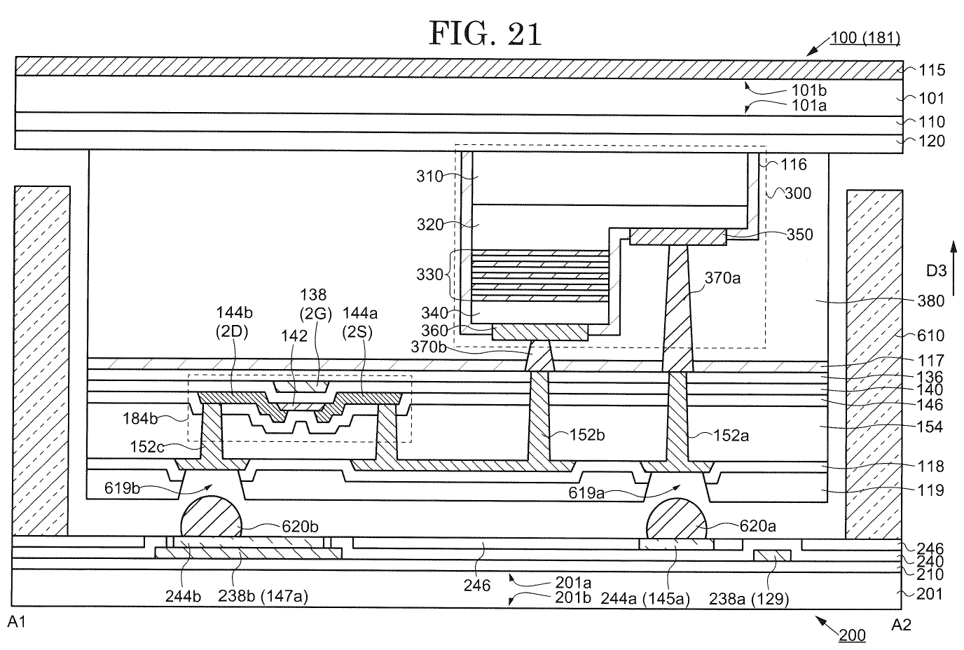

One example of a method for manufacturing the display device 10 will be described with reference to FIG. 6 to FIG. 21. FIG. 6 is a flowchart showing one example of a method for manufacturing the light-emitting diode 300 of the array substrate 100. FIG. 7 to FIG. 10 are cross-sectional views showing one example of a cross-sectional structure in a manufacturing process of the array substrate 100. FIG. 11 is a flowchart showing one example of a method for manufacturing the transistor 184 of the array substrate 100. FIG. 12 to FIG. 15 are cross-sectional views showing one example of a cross-sectional structure in the manufacturing process of the array substrate 100. FIG. 16 is a plan view showing one example of a method for manufacturing the array substrate 100. FIG. 17 is an enlarged view of the plane shown in FIG. 16. FIG. 18 is a flowchart showing one example of a method for manufacturing the backplane 200 and one example of a method for bonding the pixel IC chip 181 to the backplane 200. FIG. 19 to FIG. 20 are cross-sectional views showing one example of a cross-sectional structure in a manufacturing process of the backplane 200. FIG. 21 is a cross-sectional view illustrating one example of a cross-sectional structure in a manufacturing process of the display device 10. Configurations that are the same as or similar to those in FIG. 1 to FIG. 5 will be described as necessary.

First, a method for manufacturing the array substrate 100 and the pixel IC chip 181 will be described with reference to FIG. 6 to FIG. 17. The method for manufacturing the array substrate 100 and the pixel IC chip 181 includes steps S110 to S380. The method for manufacturing the array substrate 100 and the pixel IC chip 181 uses the first substrate 101 such as a sapphire substrate or an amorphous glass substrate as a support substrate.

Step S110 is a step of forming the underlayer 110 on the first surface 101a of the first substrate 101 to be in contact with the first surface 101a (see FIG. 6 and FIG. 7). For example, the underlayer 110 is formed using sputtering. The underlayer 110 may be a single layer or a stacked layer. For example, the underlayer 110 may be a single layer of a silicon nitride (SiNₓ) film, or a stacked layer of a silicon oxide (SiOₓ) film and a silicon nitride (SiNₓ) film. The underlayer 110 can prevent impurities from the first substrate 101 or from the outside (for example, moisture or sodium (Na)) from diffusing into layers stacked on the underlayer 110.

Step S120 is a step of forming the buffer layer 120 on the underlayer 110 to be in contact with the underlayer 110 (see FIG. 6 and FIG. 7). For example, the buffer layer 120 is formed using sputtering. The buffer layer 120 may be a single layer or a stacked layer. In addition, the buffer layer 120 may be c-axis aligned with respect to the first substrate 101. By providing the buffer layer 120, the crystallinity of the gallium nitride layer 310 of the light-emitting diode 300 can be improved. Light emitted from the light-emitting layer 330 of the light-emitting diode 300 is transmitted through the buffer layer 120 and emitted to the outside. Therefore, the buffer layer 120 has light transmittance. For example, a light-transmitting film such as an aluminum nitride (AlN) film can be used for the buffer layer 120.

Steps S130 to S200 are steps for forming the light-emitting diode 300 (see FIG. 6 and FIG.

Step S130 is a step of depositing a gallium nitride (GaN) film on the buffer layer 120 to be in contact with the buffer layer 120. Step S140 is a step of depositing a silicon (Si)-doped gallium nitride film on the gallium nitride film to be in contact with the gallium nitride film. Step S150 is a step of depositing a laminated film in which an indium gallium nitride (InGaN) film and a gallium nitride film are alternately stacked on the silicon-doped gallium nitride film to be in contact with the silicon-doped gallium nitride film. Step S160 is a step of depositing a magnesium (Mg)-doped gallium nitride film on the laminated film in which the indium gallium nitride film and the gallium nitride film are alternately stacked. Steps S130 to S160 are steps of depositing each film using sputtering.

Step S170 is a step of forming the gallium nitride layer 310, the n-type semiconductor layer 320, the light-emitting layer 330, and the p-type semiconductor layer 340 using photolithography and etching. The gallium nitride layer 310 includes the gallium nitride film deposited in step S130. Since the gallium nitride layer 310 is in contact with the buffer layer 120, the crystal growth of the gallium nitride layer 310 is controlled by the buffer layer 120. Specifically, the gallium nitride layer 310 includes a gallium nitride (GaN) film that is c-axis aligned with respect to the first substrate 101. The n-type semiconductor layer 320 includes the silicon-doped gallium nitride film deposited in step S140. A part of the surface of the n-type semiconductor layer 320 is etched and exposed. The light-emitting layer 330 includes the laminated film in which the indium gallium nitride film and the gallium nitride film are alternately stacked, which was deposited in step S150. The p-type semiconductor layer 340 includes the magnesium-doped gallium nitride film deposited in step S160.

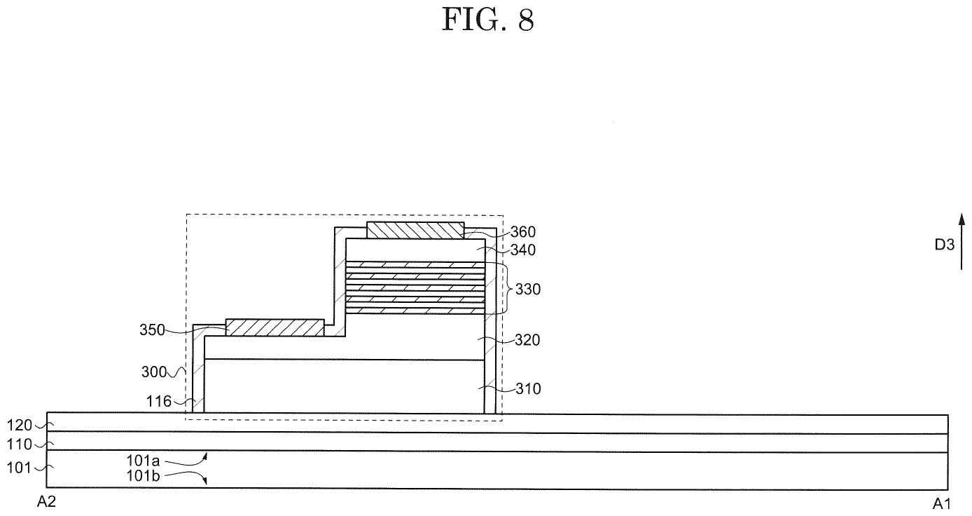

Step S180 is a step of forming the insulating layer 116 to cover and be in contact with a part of the surface of the buffer layer 120, the side surface of the gallium nitride layer 310, the side surface and a part of the surface of the n-type semiconductor layer 320, the side surface of the light-emitting layer 330, and the side surface and a part of the surface of the p-type semiconductor layer 340 (see FIG. 6 and FIG. 8). For example, the insulating layer 116 is formed by depositing an aluminum oxide (AlOₓ) film using sputtering, and then using photolithography and etching. Since the aluminum oxide (AlOₓ) film has high resistance to hydrogen, water, and the like, the insulating layer 116 functions as a protective film that protects the light-emitting diode 300. Specifically, the insulating layer 116 can prevent hydrogen, water, and the like from entering the light-emitting diode 300 and prevent hydrogen, water, and the like from diffusing inside the light-emitting diode 300. For example, when the insulating layer 116 is silicon nitride (SiNₓ), which has a refractive index greater than that of a silicon oxide (SiOₓ) film, the insulating layer 116 can reflect outgoing light from the light-emitting diode 300. As a result, the insulating layer 116 can suppress variations in the electrical characteristics of the transistor 184 due to the outgoing light from the light-emitting diode 300.

Step S190 is a step of forming the p-type electrode 360 on the p-type semiconductor layer 340. A specific example of step S190 is described below. Using photolithography and etching, a part of the insulating layer 116 is opened, and a part of the p-type semiconductor layer 340 is exposed. In addition, using sputtering, a metal film such as palladium (Pd) or gold (Au), or a stacked metal film such as a stacked layer of nickel (Ni) and gold (Au), is formed on a part of the p-type semiconductor layer 340 and on the insulating layer 116, and using photolithography and etching, the p-type electrode 360 is formed on the p-type semiconductor layer 340. The p-type electrode 360 includes a metal film such as palladium or gold, or a stacked metal film such as the stacked layer of nickel (Ni) and gold (Au). The p-type electrode 360 is electrically connected to the p-type semiconductor layer 340.

Step S200 is a step of forming the n-type electrode 350 on the n-type semiconductor layer 320. A specific example of step S200 is described below. Using photolithography and etching, a part of the insulating layer 116 is opened, and a part of the n-type semiconductor layer 320 is exposed. In addition, a metal film such as indium (In), or a stacked metal film such as a stacked layer of titanium (Ti), aluminum titanium (AlTi), and gold (Au), is deposited on a part of the n-type semiconductor layer 320 and on the insulating layer 116 using sputtering, and the n-type electrode 350 is formed on the n-type semiconductor layer 320 using photolithography and etching. The n-type electrode 350 includes a metal film such as indium, or a stacked metal film such as the stacked layer of titanium, aluminum titanium, and gold. The n-type electrode 350 is electrically connected to the n-type semiconductor layer 320.

The n-type electrode 350 and the p-type electrode 360 are insulated from each other by the insulating layer 116. That is, the n-type electrode 350 and the p-type electrode 360 are not short-circuited by the insulating layer 116.

In addition, the order of step S200 and step S190 may be reversed. Furthermore, after the p-type electrode 360 and the n-type electrode 350 are formed by a manufacturing method similar to steps S190 and S200, the insulating layer 116 may be formed by a manufacturing method similar to step S180.

As described above, the light-emitting diode 300 is formed.

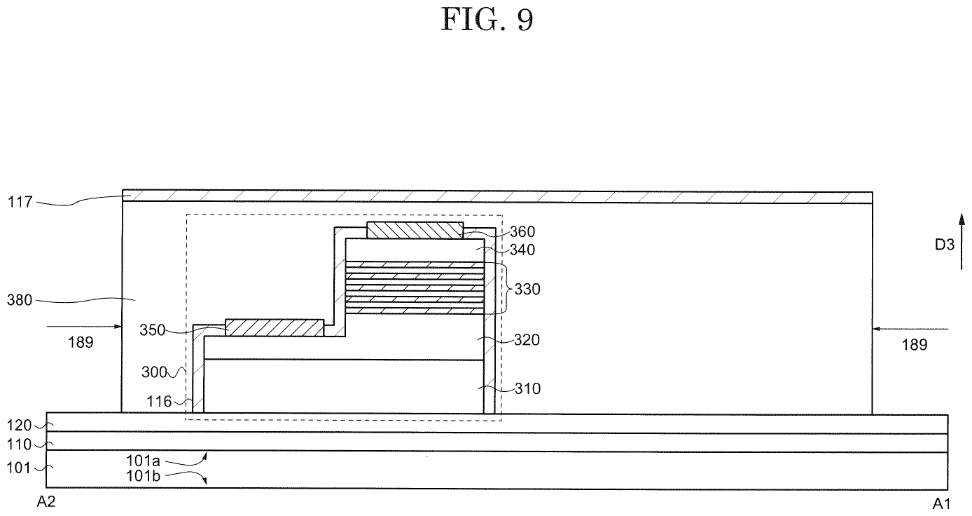

Step S210 is a step of forming the insulating layer 380 to cover a part of the surface of the buffer layer 120, the light-emitting diode 300, and the insulating layer 116 (see FIG. 6 and FIG. 9). In addition, step S210 is a step of forming the insulating layer 117 on the insulating layer 380 (see FIG. 6 and FIG. 9). Specifically, the insulating layer 380 is deposited using an apparatus for applying a film to a substrate surface (coating apparatus) to cover a part of the surface of the buffer layer 120, the light-emitting diodes 300, and the insulating layer 116, and the insulating layer 117 is deposited on the insulating layer 380 using sputtering. The insulating layer 380 and the insulating layer 117 are formed using photolithography and etching. As a result, a groove 189 is formed around each of a plurality of light-emitting diodes 300. Although details will be described later, each of the plurality of light-emitting diodes 300 can be singulated by the groove 189. For example, a spin coater or a slit coater can be used as the coating apparatus.

For example, an organic insulating film such as an acrylic resin film or a polyimide resin film can be used for the insulating layer 380. Since the insulating layer 380 includes an organic insulating film, unevenness due to the light-emitting diode 300 and the insulating layer 116 can be planarized. The insulating layer 380 may be a single layer or a stacked layer. When the insulating layer 380 is a laminated film, it may include not only an organic insulating film but also an inorganic insulating film such as a silicon oxide (SiOₓ) film or a silicon nitride (SiNₓ) film.

The insulating layer 117 is formed using a material similar to that of the insulating layer 116. example, the insulating layer 117 is formed using an aluminum oxide (AlOₓ) film. Similar to the insulating layer 116, the insulating layer 117 can prevent hydrogen, water, and the like from entering the insulating layer 380 and the transistor 184, and can prevent hydrogen, water, and the like from diffusing inside the insulating layer 380 and the transistor 184. In addition, when the refractive index of the insulating layer 117 is greater than the refractive index of silicon oxide (SiOₓ), similar to the insulating layer 116, the insulating layer 117 can reflect the outgoing light from the light-emitting diode 300. As a result, similar to the insulating layer 116, the insulating layer 117 can suppress variations in the electrical characteristics of the transistor 184 due to the outgoing light from the light-emitting diodes 300.

Step S220 is a step of forming the opening 372b and the opening 372a using photolithography and etching (see FIG. 6 and FIG. 10). The opening 372a exposes the insulating layers 117 and 380 serving as sidewalls of the opening 372a, and a part of the surface of the n-type electrode 350. The opening 372b exposes the insulating layers 117 and 380 serving as sidewalls of the opening 372b, and a part of the surface of the p-type electrode 360.

Step S230 is a step of depositing and forming the second connecting conductive layers 370a and 370b (see FIG. 6 and FIG. 10). Step S230 deposits a conductive film on the insulating layers 117 and 380 serving as the sidewalls of the opening 372a, a part of the surface of the n-type electrode 350, the insulating layers 117 and 380 serving as the sidewalls of the opening 372b, and a part of the surface of the p-type electrode 360, using sputtering. In addition, step S230 is a step of forming the second connecting conductive layer 370a on the insulating layers 117 and 380 serving as the sidewalls of the opening 372a and a part of the surface of the n-type electrode 350, and forming the second connecting conductive layer 370b on the insulating layers 117 and 380 serving as the sidewalls of the opening 372b and a part of the surface of the p-type electrode 360, using photolithography and etching. The conductive film includes the second connecting conductive layers 370a and 370b. For example, a stacked metal film of aluminum and titanium (Al/Ti film) or the like can be used for the conductive film. The second connecting conductive layer 370a is electrically connected to the n-type electrode 350, and the second connecting conductive layer 370b is electrically connected to the p-type electrode 360.

Step S240 is a step of forming the insulating layer 136 on the surfaces of the insulating layer 117 and the second connecting conductive layers 370a and 370b to be in contact with the insulating layer 117 and the second connecting conductive layers 370a and 370b (see FIG. 11 and FIG. 12). For example, the insulating layer 136 can be formed using a material similar to that of the underlayer 110 in the same manner as the underlayer 110.

Steps S250 to S310 are steps of forming the transistor 184 (see FIG. 11 to FIG. 13).

Step S250 is a step of depositing the conductive layer 138 on the insulating layer 136 to be in contact with the insulating layer 136, using sputtering. For example, the conductive layer 138 is formed using a metal film containing a common metal. For example, the common metal includes a metal film containing aluminum (Al), titanium (Ti), chromium (Cr), cobalt (Co), nickel (Ni), molybdenum (Mo), hafnium (Hf), tantalum (Ta), tungsten (W), bismuth (Bi), silver (Ag), or copper (Cu), or an alloy or a compound thereof. The conductive layer 138 may be a single layer or a stacked layer.

Step S260 is a step of processing the conductive layer 138 deposited in step S250 using photolithography and etching to form a gate electrode and wiring. The conductive layer 138 functions as the gate electrodes 1G, 2G, and 3G. For example, the conductive layer 138 shown in FIG. 12 is the gate electrode 2G.

Step S270 is a step of depositing the gate insulating layer 140 on the conductive layer 138 and on the surface of the insulating layer 136 to be in contact with the conductive layer 138 and the insulating layer 136, using sputtering. For example, silicon oxide (SiOₓ) can be used for the gate insulating layer 140.

Step S280 is a step of depositing the oxide semiconductor layer 142 on the gate insulating layer 140 to be in contact with the gate insulating layer 140, using sputtering. For example, a metal oxide having semiconductor characteristics can be used for the oxide semiconductor layer 142. Specifically, an oxide semiconductor containing indium, gallium (Ga), zinc (Zn), and oxygen (O), an oxide semiconductor containing indium, tin (Sn), zinc, and oxygen, or the like can be used. In addition, the oxide semiconductor layer 142 may be amorphous or may be crystalline. Furthermore, the oxide semiconductor layer 142 may include both amorphous and crystalline structures.

Step S290 is a step of processing the oxide semiconductor layer 142 deposited in step S280 using photolithography and etching to form the oxide semiconductor layer 142 used for the semiconductor layer of each of the plurality of transistors 184. The oxide semiconductor layer 142 functions as the channel of the transistor 184. For example, the oxide semiconductor layer 142 shown in FIG. 12 functions as the channel of the second transistor 184b.

Step S300 is a step of depositing the conductive layer 144 on the oxide semiconductor layer 142 and on a part of the gate insulating layer 140 to be in contact with the oxide semiconductor layer 142 and a part of the gate insulating layer 140, using sputtering. For example, the conductive layer 144 can be formed using a material similar to that of the conductive layer 138 in the same manner as the conductive layer 138.

For example, the conductive layer 144 includes a stacked structure of a layer containing titanium and a layer containing aluminum. Specifically, the conductive layer 144 may include a three-layer structure (such as Ti/Al/Ti or TiN/Al/TiN) in which titanium or titanium nitride (TiN) and aluminum are sequentially stacked. In addition, the conductive layer 144 may include a five-layer structure (such as TiN/Ti/Al/TiN/Ti) in which titanium or titanium nitride (TiN) and aluminum are sequentially stacked. When the conductive layer 144 includes a stacked structure of layers using titanium or titanium nitride, it is preferable to use a layer using titanium or titanium nitride for the layer where the conductive layer 144 is in contact with the oxide semiconductor layer 142. Titanium and titanium nitride have high hydrogen storage properties, and the conductive layer 144 functions as a protective film that protects the oxide semiconductor layer 142. By using titanium and titanium nitride for the conductive layer 144, the conductive layer 138 can absorb hydrogen discharged from the layer in contact with the conductive layer 138 during heat treatment in the manufacturing process of the display device 10, thereby suppressing the diffusion of hydrogen into the oxide semiconductor layer 142.

Step S310 is a step of processing the conductive layer 144 deposited in step S300 using photolithography and etching to form the source electrode, drain electrode, and wiring. The conductive layer 144 functions as the source electrode, drain electrode, or wiring. For example, the conductive layer 144 shown in FIG. 12 is the source electrode 144a and the drain electrode 144b. The source electrode 144a and the drain electrode 144b are formed in the same layer and are arranged spaced apart from each other on the oxide semiconductor layer 142 and on a part of the gate insulating layer 140.

As described above, the transistor 184 is formed.

Step S320 is a step of depositing the insulating layer 146 on the conductive layer 144 and on a part of the gate insulating layer 140 to be in contact with the conductive layer 144 and the gate insulating layer 140 using sputtering, and forming the insulating layer 154 on the insulating layer 146 to be in contact with the insulating layer 146. For example, the insulating layer 146 can be formed using a material similar to that of the gate insulating layer 140 in the same manner as the gate insulating layer 140. In addition, the insulating layer 154 can be formed using a material similar to that of the insulating layer 380 in the same manner as the insulating layer 380. Similar to the insulating layer 380, the insulating layer 154 can planarize unevenness due to the transistor 184 and the insulating layer 146.

Step S330 is a step of forming the openings 151a to 151d using photolithography and etching. The opening 151a exposes the insulating layer 136, the gate insulating layer 140, the insulating layers 146 and 154 serving as sidewalls of the opening 151a, and a part of the surface of the second connecting conductive layer 370a. The opening 151b exposes the insulating layer 136, the gate insulating layer 140, the insulating layers 146 and 154 serving as sidewalls of the opening 151b, and a part of the surface of the second connecting conductive layer 370b. The opening 151c exposes the insulating layers 146 and 154 serving as sidewalls of the opening 151c, and a part of the surface of the drain electrode 144b. The opening 151d exposes the insulating layers 146 and 154 serving as sidewalls of the opening 151d, and a part of the surface of the source electrode 144a.

Step S340 is a step of depositing a conductive film and forming a bump. The conductive layers 152a to 152c include the conductive film, and the conductive layers 152a and 152c function as bumps, and the conductive layer 152b functions as wiring. Specifically, step S340 includes depositing a conductive film on the insulating layer 154, the insulating layer 136 serving as sidewalls of the opening 151a, the gate insulating layer 140, the insulating layers 146 and 154, and a part of the surface of the second connecting conductive layer 370a using sputtering and electrochemical plating (ECP). In addition, step S340 includes depositing a conductive film on the insulating layer 136 serving as sidewalls of the opening 151b, the gate insulating layer 140, the insulating layers 146 and 154, and a part of the surface of the second connecting conductive layer 370b using sputtering and electrochemical plating (ECP), depositing a conductive film on the insulating layers 146 and 154 serving as sidewalls of the opening 151c and a part of the surface of the drain electrode 144b, and depositing a conductive film on the insulating layers 146 and 154 serving as sidewalls of the opening 151d and a part of the surface of the source electrode 144a. Furthermore, step S340 includes forming the conductive layer 152a on a part of the insulating layer 154, the insulating layer 136 serving as sidewalls of the opening 151a, the gate insulating layer 140, the insulating layers 146 and 154, and a part of the surface of the second connecting conductive layer 370a using photolithography and etching. In addition, similar to the formation of the conductive layer 152a, step S340 includes forming the conductive layer 152b on a part of the insulating layer 154, the insulating layer 136 serving as sidewalls of the opening 151b, the gate insulating layer 140, the insulating layers 146 and 154, a part of the surface of the second connecting conductive layer 370b, the insulating layers 146 and 154 serving as sidewalls of the opening 151d, and a part of the surface of the source electrode 144a. Furthermore, the conductive layer 152c is formed on the insulating layers 146 and 154 serving as sidewalls of the opening 151c and a part of the surface of the drain electrode 144b.

For example, a hydrogen storage metal can be used for the conductive film deposited step S340. For example, the hydrogen storage metal is copper, titanium, zirconium (Zr), palladium (Pd), magnesium (Mg), manganese (Mn), and an alloy containing at least one of these metals. That is, the conductive layer 152 contains the hydrogen storage metal. For example, a conductive layer composed of manganese and copper can be used for the conductive layer containing at least one metal of the hydrogen storage metals. By using the conductive layer composed of the layer containing manganese and copper for the conductive layer 152, manganese oxide (MnO) is formed between the conductive layer 152 and the insulating layer in contact with the conductive layer 152. As a result, the display device 10 can suppress the diffusion of copper into the insulating layer in contact with the conductive layer 152, absorb hydrogen discharged from the insulating layer in contact with the conductive layer 152, and suppress deterioration in electrical characteristics of the transistor 184 including the oxide semiconductor layer 142. In addition, since the conductive layer 152 is formed using ECP, it can be formed thicker than the conductive layer 138 and the conductive layer 144. Therefore, the resistance values of the signal lines, potential lines, and wiring including the conductive layer 152 can be reduced.

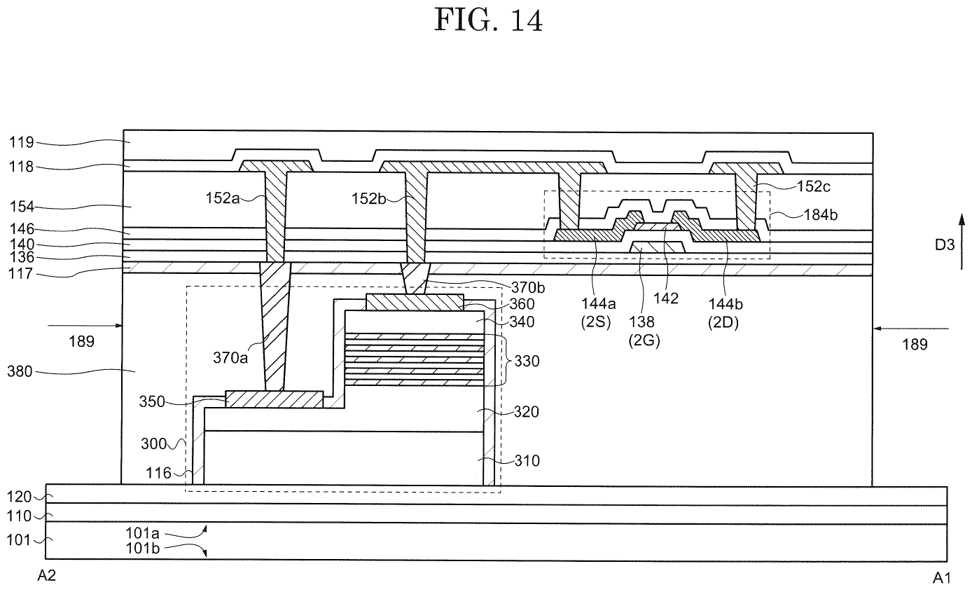

Step S350 is a step of forming the insulating layer 118 to cover a part of the surface of the insulating layer 154 and the conductive layers 152a to 152c (see FIG. 11 and FIG. 14). In addition, step S350 is a step of forming the insulating layer 119 on the insulating layer 118 (see FIG. 11 and FIG. 14). Specifically, the insulating layer 118 is deposited on a part of the surface of the insulating layer 154 and on the conductive layers 152a to 152c using sputtering, and the insulating layer 119 is deposited on the insulating layer 118 using the apparatus for applying a film to a substrate surface (coating apparatus). The insulating layer 118 and the insulating layer 119 are formed using photolithography and etching. As a result, similar to step S210, the groove 189 is formed around each of the plurality of light-emitting diodes 300.

For example, the insulating layer 118 is formed using a material similar to that of the insulating layer 116, and the insulating layer 119 is formed using a material similar to that of the insulating layer 380. For example, the insulating layer 118 is formed using an aluminum oxide (AlOₓ) film. Similar to the insulating layer 116, the insulating layer 118 can prevent hydrogen, water, and the like from entering the insulating layer 154 and the transistor 184, and can prevent hydrogen, water, and the like from diffusing inside the insulating layer 154 and the transistor 184. As a result, similar to the insulating layer 116, the insulating layer 119 can suppress variations in electrical characteristics of the transistor 184 due to hydrogen, water, and the like. In addition, similar to the insulating layer 380, the insulating layer 119 can planarize unevenness due to the insulating layer 118 and the conductive layers 152a, 152b, and 152c.

Step S360 is a step of forming the openings 619a and 619b using photolithography and etching. The opening 619a exposes the insulating layers 118 and 119 serving as sidewalls of the opening 619a, and a part of the surface of the conductive layer 152a. The opening 619b exposes the insulating layers 118 and 119 serving as sidewalls of the opening 619b, and a part of the surface of the conductive layer 152c. In addition, similar to step S210, the groove 189 is formed around each of the plurality of light-emitting diodes 300.

Step S370 is a step of forming the color conversion layer 115 on the second surface 101b of the first substrate 101. In this case, step S370 will be described with reference to FIG. 11 and FIG. 15 to FIG. 17. As shown in FIG. 16, the second surface 101b side of the array substrate 100 overlaps a peripheral region 156 and a pixel chip region 185. The peripheral region 156 overlaps a plurality of alignment markers 157 and includes the plurality of alignment markers 157. The pixel chip region 185 overlaps a bank region 155, the plurality of pixel IC chips 181, and the groove 189, and includes the bank region 155, the plurality of pixel IC chips 181, and the groove 189 (see FIG. 17). The b ank region 155 includes a bank 155a. The plurality of alignment markers 157 is used when singulating the plurality of pixel IC chips 181. Specifically, step S370 is a step of applying an acrylic resin using the coating apparatus and forming the plurality of alignment markers 157 and the bank 155a on the second surface 101b using photolithography and etching. In addition, for example, the color conversion layer 115 is applied using a coating apparatus to overlap the pixel chip region 185 inside the bank 155a. The bank 155a has a function of blocking the color conversion layer 115 from leaking to the outside of the bank 155a (the peripheral region 156). That is, the bank 155a can suppress the color conversion layer 115 from leaking to the outside of the bank 155a.

For example, the color conversion layer 115 contains quantum dots. For example, the color conversion layer 115 may contain quantum dots that convert blue light emitted by the light-emitting diode 300 into red light, may contain quantum dots that convert blue light emitted by the light-emitting diode 300 into green light, or may contain both. Either quantum dots that convert blue light into red light or quantum dots that convert blue light into green light may be formed to be applied to each pixel 180.

As described above, the array substrate 100 is formed.

Step S380 is a step of singulating the array substrate 100 including the plurality of pixel IC chips 181 into individual pixel IC chips 181. Specifically, for example, the array substrate 100 is singulated into individual pixel IC chips 181 using a laser with reference to the alignment markers 157 (see FIG. 16). In this case, the laser singulates the array substrate 100 into individual pixel IC chips 181 along the groove 189 with reference to the alignment markers 157. As shown in FIG. 17, the array substrate 100 is singulated such that the length of the pixel IC chip 181 in the first direction D1 is a length TW, and the length of the pixel IC chip 181 in the second direction D2 is a length TH.

As described above, the pixel IC chip 181 is formed.

Next, a method for manufacturing the backplane 200 and a method for bonding the pixel IC chip 181 and the backplane 200 will be described with reference to FIG. 18 to FIG. 21. The method for manufacturing the backplane 200 includes steps S400 to S460. The method for manufacturing the backplane 200 uses the second substrate 201, such as an amorphous glass substrate, as a support substrate.

Step S400 is a step of forming the underlayer 210 on the first surface 201a of the second substrate 201 to be in contact with the first surface 201a (see FIG. 18 and FIG. 19). For example, the underlayer 210 can be formed using a material similar to that of the underlayer 110 in step S110. Similar to the underlayer 110, the underlayer 210 can prevent impurities from the second substrate 201 or from the outside (for example, moisture or sodium (Na)) from diffusing into the layers stacked on the underlayer 210.

Step S410 is a step of depositing a conductive film on the underlayer 210 to be in contact with the underlayer 210 (see FIG. 18 and FIG. 19). In addition, step S420 is a step of processing the conductive film formed in step S410 using photolithography and etching to form the plurality of scanning signal lines 129, driving potential lines 147, and wiring (see FIG. 18 and FIG. 19). For example, the conductive layers 238a and 238b shown in FIG. 19 contain the conductive film, the conductive layer 238a functions as the scanning signal line 129, and the conductive layer 238b functions as the driving potential line 147a. For example, the conductive layers 238 a and 238b can be deposited using a material similar to that of the conductive layers 152a to 152c and can be formed in the same manner.

Step S430 is a step of depositing the insulating layer 240 on the conductive layers 238a and 238b and on the surface of the underlayer 210 to be in contact with the conductive layers 238a and 238b and the underlayer 210 using sputtering (see FIG. 18 and FIG. 19). For example, the insulating layer 240 can be formed using a material similar to that of the gate insulating layer 140 and the insulating layer 146 and can be formed in the same manner as the gate insulating layer 140 and the insulating layer 146.

Step S440 is a step of forming the opening 243 using photolithography and etching (see FIG. 18 and FIG. 19). The opening 243 exposes the insulating layer 240 serving as the sidewall of the opening 243 and a part of the surface of the conductive layer 238b.

Step S450 is a step of depositing a conductive film to be in contact with the insulating layer 240 and a part of the surface of the conductive layer 238b (see FIG. 18 and FIG. 20). In addition, step S460 is a step of processing the conductive film formed in step S450 using photolithography and etching to form the plurality of data signal lines 131, ground wirings 145, first connecting conductive layers 244, and wiring (see FIG. 18 and FIG. 20). For example, the first connecting conductive layers 244a and 244b shown in FIG. 20 contain the conductive film, the first connecting conductive layer 244a functions as the ground wiring 145a, and the first connecting conductive layer 244b is electrically connected to the conductive layer 238 b and functions as the driving potential line 147a. Although not shown, the first connecting conductive layers 244c and 244d are formed in the same manner as the first connecting conductive layers 244a and 244b by steps S450 and S460. The first connecting conductive layer 244c (see FIG. 3) is electrically connected to the conductive layer 238a and functions as the scanning signal line 129. The first connecting conductive layer 244d (see FIG. 3) functions as the data signal line 131. For example, the first connecting conductive layer 244 can be deposited using a material similar to that of the conductive layers 238a and 238b and the conductive layers 152a to 152c and can be formed in the same manner. Although not shown, the first connecting conductive layer 244c is electrically connected to the scanning signal line 129 via a connecting member 620 different from the connecting member 620a and the connecting member 620b. The connecting member 620 that electrically connects the first connecting conductive layer 244c and the scanning signal line 129 may be referred to as a conductor (third conductor).

For example, the data signal line 131 (the first connecting conductive layer 244d) and the ground wiring 145a (the first connecting conductive layer 244a) are formed using copper. The resistance values of the data signal line 131 and the ground wiring 145a can be made smaller than the resistance values of wiring formed using a material with a higher specific resistance than copper. As a result, compared to the wiring formed using the material with a higher specific resistance than copper, the time constant of the signal supplied to the data signal line 131 is improved, and the charge supply amount of the potential supplied to the ground wiring 145a increases.

As described above, the backplane 200 is formed.

Step S470 is a step of bonding the singulated pixel IC chips 181 and the backplane 200.

Step S470 is a step of bonding the singulated pixel IC chips 181 and the backplane 200 (see FIG. 18 and FIG. 21). The adhesive resin material 610 is deposited on the buffer layer 120 using the coating device. In addition, the adhesive resin material 610 is formed using photolithography and etching to surround at least a part of the periphery of the light-emitting diode 300 and the transistor 184. Furthermore, the conductive connecting members 620a and 620b are formed on the first connecting conductive layers 244 (in this case, the first connecting conductive layers 244a and 244b). For example, solder or an anisotropic conductive film (ACF) or the like can be used for the conductive connecting members 620a and 620b. In addition, the pixel IC chip 181 (the first surface 101a of the array substrate 100) is arranged to face the first surface 201a of the backplane 200, and the pixel IC chip 181 and the backplane 200 are bonded together by the adhesive resin material 610. In this case, the conductive connecting members 620a and 620b are in contact with the openings 619a and 619b and are electrically connected to the conductive layers 152a and 152c. That is, the connecting member 620a is electrically connected to the light-emitting diode 300 via the opening 619a, and the connecting member 620b is electrically connected to the transistor 184 via the opening 619b. For example, the adhesive resin material 610 may be formed on the second substrate 201 instead of on the first substrate 101, and the conductive connecting members 620a and 620b may be formed on the conductive layers 152a and 152c instead of on the first connecting conductive layers 244.

Steps S480 to S500 are steps of pressure-bonding the bonded pixel IC chip 181 and backplane 200, and pre-curing and fully curing the connecting member 620. The method for manufacturing the display device 10 includes steps S490 and S500, but the method for manufacturing the display device 10 may perform only full curing of the connecting members 620 without performing pre-curing and full curing of the connecting members 620 in stages as in steps S490 and S500. By steps S480 to S500, the conductive layer 152a of the pixel IC chip 181 (the array substrate 100) is electrically connected to the first connecting conductive layer 244a of the backplane 200 via the connecting member 620a, and the conductive layer 152c of the pixel IC chip 181 (the array substrate 100) is electrically connected to the first connecting conductive layer 244b of the backplane 200 via the connecting member 620b.

As described above, the method for manufacturing the display device 10 can electrically connect the pixel IC chip 181 (the first surface 101a of the array substrate 100) and the backplane 200. As a result, the pixel IC chip 181 including the light-emitting diode 300 and the first transistor 184a to the third transistor 184c is electrically connected to the data signal line 131, the scanning signal line 129, the ground wiring 145, and the driving potential line 147 included in the backplane 200.

When a light-emitting diode chip is transferred to a backplane including a transistor for driving the light-emitting diode and the light-emitting diode and the transistor are electrically connected, the contact resistance value may vary depending on the bonding between the light-emitting diode chip and the transistor. Therefore, in a display device in which the light-emitting diode chip is transferred and connected to the transistor, there is a risk that the light emission characteristics, temperature characteristics, and the like of the pixel may deteriorate. On the other hand, the light-emitting diode 300 of the display device 10 and the plurality of transistors 184 for driving the light-emitting diode 300 can be formed on the same first substrate 101. The light-emitting diode 300 and the pixel circuit 182 including the second transistor 184b for driving the light-emitting diode 300 are electrically connected on the same first substrate 101. As a result, the display device 10 can be completed as a display device with the contact resistance value between the light-emitting diode and the transistor stabilized by transferring the pixel 180 including the light-emitting diode and the transistor for driving the light-emitting diode to the backplane as a one-chip pixel IC chip 181. Since the current supplied to the light-emitting diode 300 by the second transistor 184b is stabilized, the display device 10 can suppress deterioration in the light emission and temperature characteristics of the pixel 180.

In addition, when the plurality of transistors for driving the light-emitting diode and the light-emitting diode are formed in the same process and arranged in the same layer, the electrical characteristics of the light-emitting diode depend on the electrical characteristics of the plurality of transistors. That is, it is difficult to optimally adjust the electrical characteristics of the plurality of transistors for driving the light-emitting diode and the light-emitting diode for each device. On the other hand, the plurality of transistors 184 for driving the light-emitting diode 300 of the display device 10 is formed in a different process from the light-emitting diode 300 and is arranged in different layers. As a result, since the configuration of the plurality of transistors 184 and the configuration of the light-emitting diode 300 can be individually optimized, the electrical characteristics of the plurality of transistors for driving the light-emitting diode and the light-emitting diode can be optimally adjusted for each device.

In addition, for example, since the plurality of transistors 184 includes the oxide semiconductor layer 142, the off-current and leakage current of the transistor 184 are smaller than the leakage current and off-current of the transistor containing amorphous silicon or polysilicon. Furthermore, the temperature characteristics of the off-current of the transistor formed using the oxide semiconductor layer are superior to the temperature characteristics of the off-current of the transistor formed using amorphous silicon or polysilicon. As a result, the display device 10 can suppress deterioration in the electrical characteristics of the light-emitting diode 300 caused by the leakage current of the transistor 184. In addition, the display device 10 can suppress deterioration in the temperature characteristics caused by the off-current and leakage current of the transistor 184.

Furthermore, the display device 10 includes a protection circuit (the third transistor 184c) for protecting the light-emitting diode 300 on the first substrate 101. Therefore, for example, there is no need to mount a protection circuit of a separate chip, and the light-emitting diode 300 is protected by the protection circuit formed on the first substrate 101, so that, for example, ESD resistance can be ensured.

As a result, the deterioration of the long-term reliability of the display device 10 is suppressed.

### 2. Second Embodiment

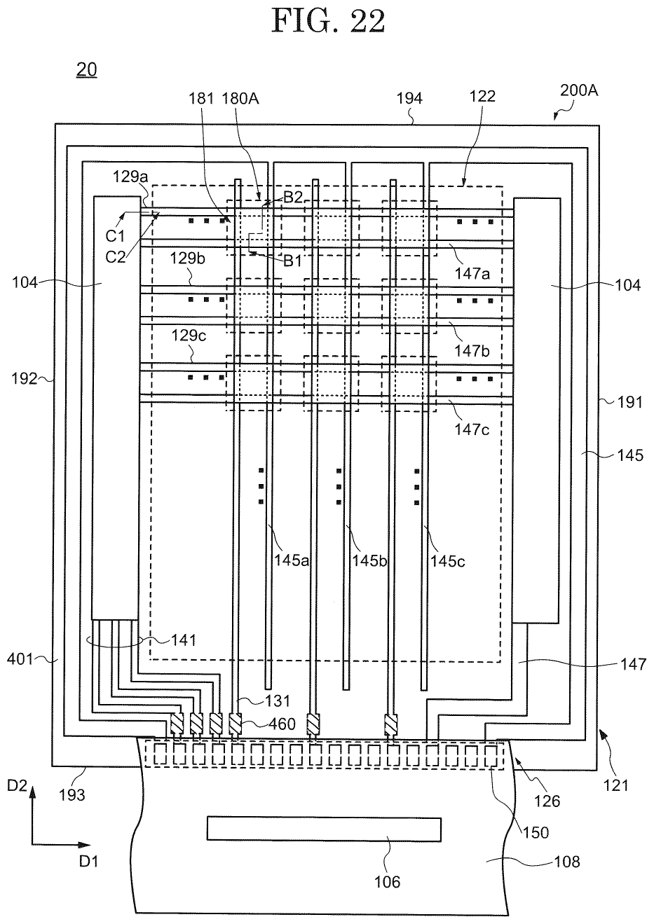

A configuration of a display device 20 will be described with reference to FIG. 22 to FIG. 31.

### 2-1. Overview of Display Device 20

An overview of the display device 20 will be described with reference to FIG. 22. FIG. 22 is a schematic plan view showing a configuration of the display device 20. Configurations that are the same as or similar to those in FIG. 1 to FIG. 21 will be described as necessary.

The display device 20 includes at least a plurality of scanning signal line driving circuits 104, a plurality of pixels 180A, and a plurality of protection circuits 460 compared to the display device 10. In addition, the display device 20 includes a backplane 200A different from the backplane 200 of the display device 20. The display device 20 includes the plurality of scanning signal line driving circuits 104 and the plurality of protection circuits 460. Other configurations of the display device 20 are similar to the configuration of the display device 20. Therefore, the configuration of the display device 20 will be described as necessary.

The display device 20 includes the plurality of pixel IC chips 181 and the backplane 200A electrically connected to the plurality of pixel IC chips 181.

The plurality of scanning signal line driving circuits 104 is arranged on the first substrate 101 and overlaps the peripheral region 121. In addition, one of the plurality of scanning signal line driving circuits 104 is arranged on the first side 191 side, and the other of the plurality of scanning signal line driving circuits 104 is arranged on the second side 192 side. The plurality of scanning signal line driving circuits 104 includes a plurality of transistors 484.

In the description of the transistors included in the pixel 180A, when the transistors are not distinguished, the transistor is described as the transistor 484, and when the transistors are distinguished, the transistor is assigned individual reference signs such as a transistor 484a.

For example, a part of the terminal 150 in the terminal region 126 is electrically connected to the scanning signal line driving circuit 104 on the first side 191 side using a connection wiring 141. For example, the driving potential line 147 is arranged between a part of the terminal 150 in the terminal region 126 and the scanning signal line driving circuit 104 on the second side 192 side, and is electrically connected to a part of the terminal 150 in the terminal region 126 and the scanning signal line driving circuit 104 on the second side 192 side. For example, the driving potential lines 147a, 147b, and 147c extend in the direction D1 from the scanning signal line driving circuit 104 on the first side 191 side and are connected to the plurality of pixels 180A arranged in the direction D1. For example, a plurality of scanning signal lines including scanning signal lines 129a, 129b, and 129c are electrically connected to the scanning signal line driving circuit 104 on the second side 192 side, extend in the direction D1, and are connected to the plurality of pixels 180A arranged in the direction D1. The electrical connection between the terminal 150, the connection wiring 141, the plurality of scanning signal line driving circuits 104, the driving potential lines 147, 147a, 147b, and 147c, and the scanning signal line 129a, 129b, and 129c is not limited to the configuration shown in FIG. 22. For example, the scanning signal line driving circuit 104 on the first side 191 side and the scanning signal line driving circuit 104 on the second side 192 side may be symmetrically interchanged with respect to a virtual line parallel to the first direction D2, and each wiring may be interchanged. In addition, similar to the display device 20, the driving potential lines 147, 147a, 147b, and 147c may be directly connected between the terminal 150 and each pixel 180A without being electrically connected to the scanning signal line driving circuit 104.

The pixel 180A includes the pixel IC chip 181. Although details will be described later, the stacked structure of the pixel 180A is different from the stacked structure of the pixel 180. Specifically, the stacked structure of the backplane 200A of the pixel 180A is different from the stacked structure of the backplane 200 of the pixel 180.

Although details will be described later, the protection circuit 460 is arranged between the terminal 150 and each signal line. For example, the protection circuit 460 is electrically connected to the data signal line 131 and the terminal 150. In addition, for example, the protection circuit 460 is arranged between the connection wiring 141 and the terminal 150, and the protection circuit 460 is electrically connected to the connection wiring 141 and the terminal 150.

The second substrate 401 includes the first side 191, the second side 192 facing the first side, the third side 193, and the fourth side 194 facing the third side. The display region 122 and the peripheral region 121 are surrounded by the first side 191, the second side 192 facing the first side, the third side 193, and the fourth side 194 facing the third side 193 in a plan view.

For example, the driver IC 106 is arranged on the FPC 108. The driver IC 106 supplies control signal for driving the plurality of pixels 180A to the plurality of pixels 180A via the FPC 108, the plurality of scanning signal line driving circuits 104, a plurality of connection wirings 141, the plurality of data signal lines 131, the ground wiring 145, and the driving potential line 147.

### 2-2. Example of Cross Section of Display Device 20

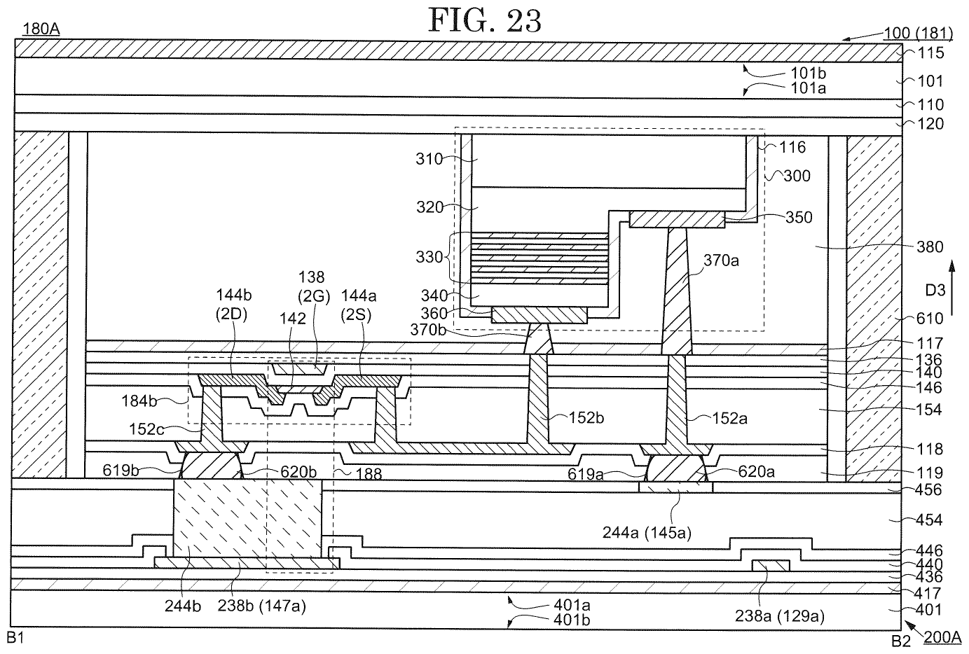

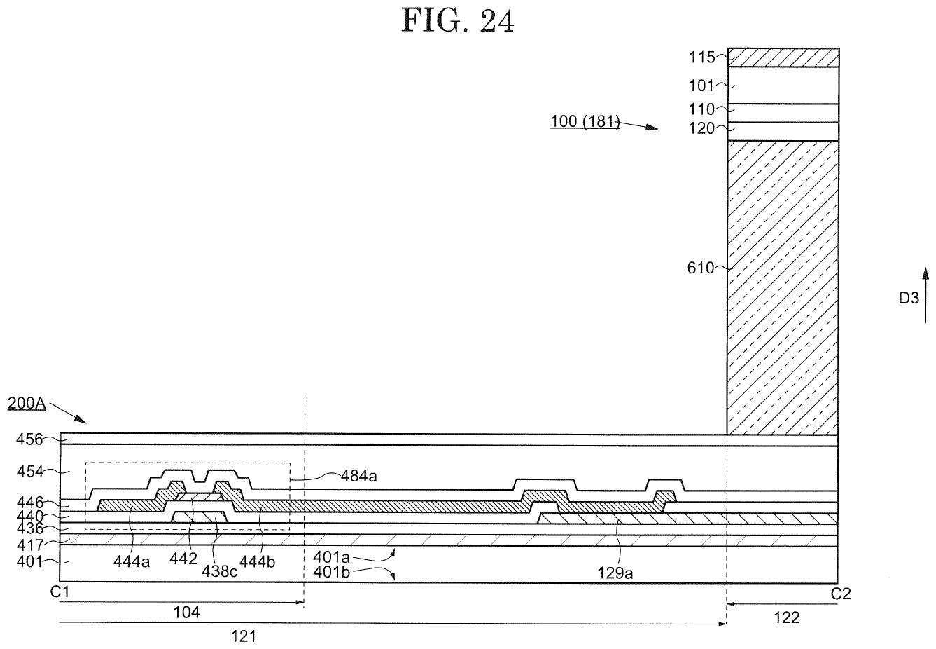

An example of a cross section of the display device 20 will be described with reference to FIG. 23 and FIG. 24. FIG. 23 is a cross-sectional view showing an example of the cross-sectional structure of the pixel 180A of the display device 20. Specifically, FIG. 23 is a cross-sectional view showing an example of the cross-sectional structure of the pixel 180A cut along a line B1-B2 shown in FIG. 22. FIG. 24 is a cross-sectional view showing an example of the cross-sectional structure of a part of the peripheral region 121 and the display region 122 of the display device 20. Specifically, FIG. 24 is a cross-sectional view showing an example of the cross-sectional structure of a part of the peripheral region 121 and the display region 122 cut along a line C1-C2 shown in FIG. 22. Configurations that are the same as or similar to those in FIG. 1 to FIG. 22 will be described as necessary.

The display device 20 includes the array substrate 100 (the pixel IC chip 181) and the backplane 200A. Since the array substrate 100 includes a configuration similar to that of the array substrate 100 of the display device 20, the description thereof will be omitted here.

As shown in FIG. 23 and FIG. 24, the backplane 200A includes a second substrate 401, a protective layer 417, an underlayer 436, the conductive layers 238a, 238b, and 438c, the first connecting conductive layers 244a and 244b, a source electrode 444a, a drain electrode 444b, an oxide semiconductor layer 442, a gate insulating layer 440, an insulating layer 446, an insulating layer 454, and an insulating layer 456. In addition, as shown in FIG. 24, the backplane 200A includes the scanning signal line 129a and the transistor 484a. The transistor 484a includes at least the source electrode 444a, the drain electrode 444b, the oxide semiconductor layer 442, a part of the gate insulating layer 440, and a part of the insulating layer 446.

The second substrate 401 is a substrate (second support substrate) that supports the plurality of terminals 150, the plurality of scanning signal line driving circuits 104, the plurality of scanning signal lines 129 including the scanning signal line 129a, the plurality of data signal lines 131, the ground wiring 145, and the driving potential line 147. The second substrate 401 includes a first surface 401a and a second surface 401b facing the first surface 401a. The protective layer 417, the underlayer 436, the conductive layers 238a, 238b, and 438c, the first connecting conductive layers 244a and 244b, the source electrode 444a, the drain electrode 444b, the oxide semiconductor layer 442, the gate insulating layer 440, the insulating layer 446, the insulating layer 454, and the insulating layer 456 are arranged on the first surface 401a.

The protective layer 417 is arranged on the first surface 401a of the second substrate 401. The protective layer 417 can prevent the diffusion of impurities from the second substrate 401 or from the outside (for example, moisture or sodium (Na)).

The underlayer 436 is arranged on the protective layer 417. Similar to the protective layer 417, the underlayer 436 can prevent the diffusion of impurities from the second substrate 401 or from the outside (for example, moisture or sodium (Na)).

The conductive layers 238a, 238b, and 438c are arranged on the underlayer 436. The conductive layer 238a functions as the scanning signal line 129a. The conductive layer 238b functions as the driving potential line 147a. The conductive layer 438 c functions as a gate electrode of the transistor 484a.

The gate insulating layer 440 is arranged on the conductive layers 238a, 238b, and 438c and on a part of the underlayer 436. That is, the gate insulating layer 440 is arranged to cover the plurality of scanning signal lines 129, the driving potential line 147a, and the gate electrode of the transistor 484a. The gate insulating layer 440 insulates the plurality of scanning signal lines 129, the driving potential line 147a, and the gate electrode of the transistor 484a from each other.

The oxide semiconductor layer 442 is arranged on the gate insulating layer 440. The oxide semiconductor layer 442 is used as a channel of the plurality of transistors 484. The plurality of transistors 484 includes the transistor 484a.

The source electrode 444a and the drain electrode 444b are arranged on the oxide semiconductor layer 442 and on the gate insulating layer 440. The source electrode 444a and the drain electrode 444b are electrically connected to the oxide semiconductor layer 442. The source electrode 444a and the drain electrode 444b of the display device 20 are connected in direct contact with the oxide semiconductor layer 442. Furthermore, in the description of the source electrode and the drain electrode included in the pixel 180A, and the wiring formed in the same layer as the source electrode and the drain electrode, when the source electrode, the drain electrode, and the wiring are not distinguished, the source electrode, the drain electrode, and the wiring are described as a conductive layer 444, and when the source electrode, the drain electrode, and the wiring are distinguished, the source electrode, the drain electrode, and the wiring are assigned individual reference signs such as the source electrode 444a and the drain electrode 444b.

The insulating layer 454 is arranged on the insulating layer 446. The insulating layer 456 is arranged on the insulating layer 454. A part of the insulating layer 456 is opened. In addition, a part of the insulating layer 454 and a part of the insulating layer 456 are opened, and the conductive layer 238b is exposed.

The first connecting conductive layer 244a is arranged on a part of the exposed insulating layer 456. In addition, the first connecting conductive layer 244b is arranged on the exposed conductive layer 238b and is electrically connected to the conductive layer 238b. The first connecting conductive layers 244a and 244b are formed on different layers in the same process. For example, the first connecting conductive layer 244a extends in the second direction D2 and branches and extends in the first direction D1 as shown in FIG. 4. Although not shown, the first connecting conductive layer 244a is arranged to overlap the gate insulating layer 440. For example, the first connecting conductive layer 244b extends in the first direction D1 and the second direction D2 as shown in FIG. 3. The first connecting conductive layer 244b may be arranged to overlap the gate insulating layer 440.

The adhesive resin material 610 is arranged on a part of the insulating layer 456. The adhesive resin material 610 is formed to surround at least a part of the periphery of the light-emitting diode 300 and the transistor 184, as shown in the cross-sectional view shown in FIG. 24. In addition, for example, the adhesive resin material 610 is arranged on a part of the insulating layer 456 so as not to overlap the peripheral region 121 but to overlap the display region 122, as shown in the cross-sectional view shown in FIG. 23. Furthermore, the adhesive resin material 610 may overlap the peripheral region 121. In addition, to prevent damage to the display device 20, the peripheral region 121 of the display device 20 (around the adhesive resin material 610) may be sealed with resin or the like.

The first surface 101a of the pixel IC chip 181 (the array substrate 100) faces the first surface 401a of the backplane 200A, and the array substrate 100 is bonded to the backplane 200A. Specifically, the array substrate 100 and the backplane 200A are bonded together by the adhesive resin material 610. As a result, the array substrate 100 is electrically connected to the backplane 200A by the conductive connecting members 620a and 620b. Specifically, the conductive layer 152a of the array substrate 100 is electrically connected to the first connecting conductive layer 244a of the backplane 200A via the conductive connecting member 620a, and the conductive layer 152c of the array substrate 100 is electrically connected to the first connecting conductive layer 244b of the backplane 200A via the conductive connecting member 620b. For example, in this case, the conductive layer 238b and the first connecting conductive layer 244b may overlap the second transistor 184b. The conductive layer 238b (the first connecting conductive layer 244b) and the oxide semiconductor layer 142 can form the capacitance element 188 via the insulating layers 119, 118, 154, and 146.

The display device 20 including the configuration as described above has the same effects as the display device 10. In addition, since the peripheral region 121 of the display device 20 includes the scanning signal line driving circuit 104, the display device 20 can reduce a step caused by the thickness of the peripheral region 121 and the thickness of the display region 122, compared to a display device that does not include the scanning signal line driving circuit 104.

### 2-3. Example of Method for Manufacturing Display Device 20

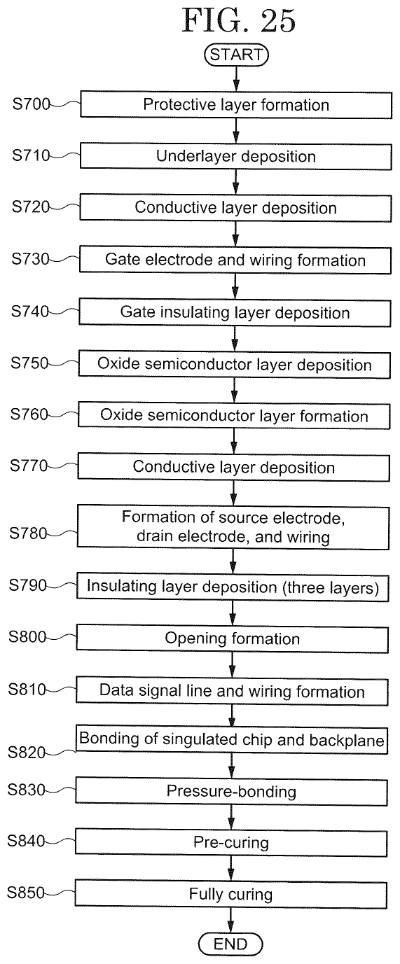

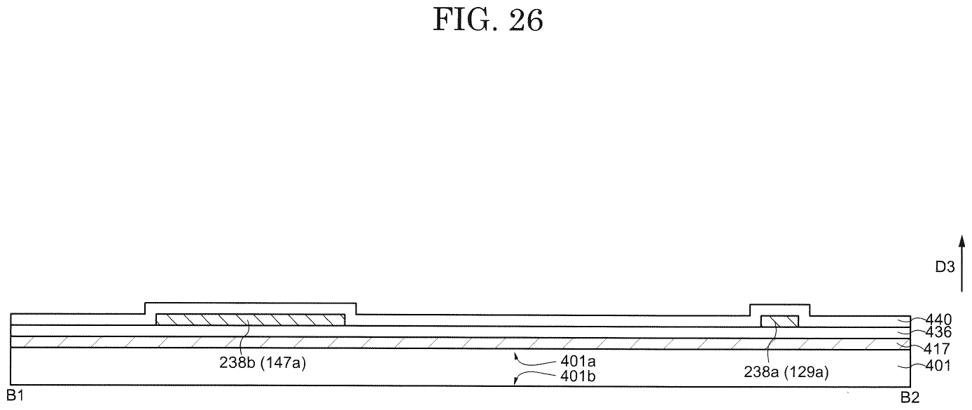

One example of a method for manufacturing the display device 20 will be described with reference to FIG. 25 to FIG. 30. FIG. 25 is a flowchart showing an example of a method for manufacturing the backplane 200A and an example of a method for bonding the pixel IC chip 181 and the backplane 200A. FIG. 26 to FIG. 30 are cross-sectional views showing an example of a cross-sectional structure in a manufacturing process of the backplane 200A. Configurations that are the same as or similar to those in FIG. 1 to FIG. 24 will be described as necessary. In addition, the method for manufacturing the array substrate 100 is the same as the method for manufacturing the array substrate 100 of the display device 10 described in “1-5”, and the method for manufacturing the array substrate 100 will be described as necessary.

The method for manufacturing the backplane 200A includes steps S700 to S810. Similar the method for manufacturing the backplane 200, the method for manufacturing the backplane 200A uses the second substrate 401 such as an amorphous glass substrate as a support substrate.

Step S700 is a step of forming the protective layer 417 on the first surface 401a of the second substrate 401 to be in contact with the first surface 401a (see FIG. 25 and FIG. 26). For example, the protective layer 417 is formed by forming a material similar to that of the insulating layer 117 in step S210 on the first surface 401a using CVD. The protective layer 417 can prevent impurities from the second substrate 401 or from the outside (for example, moisture or sodium (Na)) from diffusing into the layers stacked on the underlayer 436.

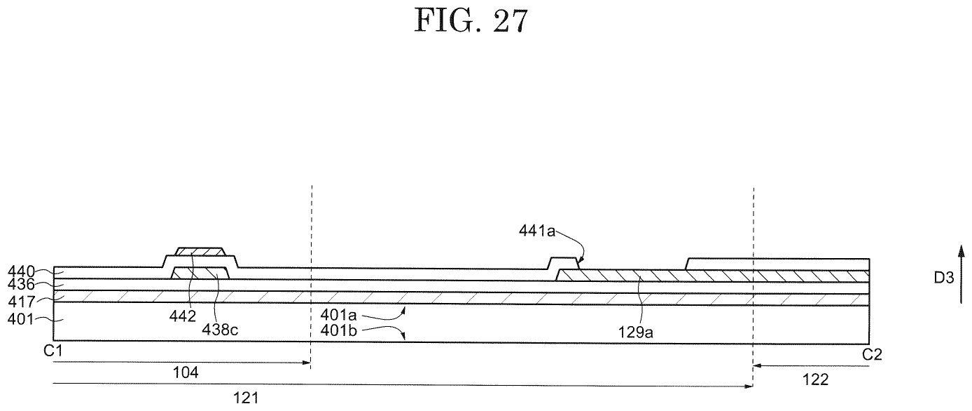

Step S710 is a step of forming the underlayer 436 on the protective layer 417 to be in contact with the protective layer 417 (see FIG. 25, FIG. 26, and FIG. 27). For example, the underlayer 436 can be formed in the same way using a material similar to that of the underlayer 110 in step S110. Similar to the protective layer 417, the underlayer 436 can prevent impurities from the second substrate 401 or from the outside (for example, moisture or sodium (Na)) from diffusing into the layers stacked on the underlayer 436.

Step S720 is a step of depositing a conductive film on the underlayer 436 to be in contact with the underlayer 436 (see FIG. 25, FIG. 26, and FIG. 27). In addition, step S730 is a step of processing the conductive film formed in step S720 using photolithography and etching to form gate electrodes of the plurality of transistors, the plurality of scanning signal lines 129a, 129b and 129c, the plurality of drive potential lines 147a, 147b and 147c, and respective wirings. For example, the conductive layers 238a and 238b shown in FIG. 26 contain the conductive film, the conductive layer 238a functions as the scanning signal line 129a, and the conductive layer 238b functions as the driving potential line 147a. In addition, the conductive layer 438c and the scanning signal line 129a shown in FIG. 27 contain the conductive film, and the conductive layer 438c functions as the gate electrode of the transistor 484a. For example, the conductive layers 238a and 238b, the conductive layer 438c, and the scanning signal line 129a are deposited by sputtering using a material similar to that of the conductive layer 138 formed in step S250, and are formed using photolithography and etching in the same manner as in step S260.

Step S740 is a step of forming the gate insulating layer 440 on the conductive layers 238a and 238b, on the conductive layer 438c and the scanning signal line 129a, and on the surface of the underlayer 436, so as to be in contact with the conductive layers 238a and 238b, the conductive layer 438c and the scanning signal line 129a, and the underlayer 436, using CVD (see FIG. 25, FIG. 26, and FIG. 27). For example, the gate insulating layer 440 can be formed using CVD using a material similar to that of the gate insulating layer 140.

Step S750 is a step of depositing the oxide semiconductor layer 442 on the gate insulating layer 440 to be in contact with the gate insulating layer 440 using sputtering (see FIG. 25, FIG. 26, and FIG. 27). For example, the oxide semiconductor layer 442 is deposited on the gate insulating layer 440 using a material similar to that of the oxide semiconductor layer 142.

Step S760 is a step of processing the oxide semiconductor layer 442 deposited in step S750 using photolithography and etching to form the oxide semiconductor layer 442 used for the semiconductor layer of each of the plurality of transistors 484 (see FIG. 25, FIG. 26, and FIG. 27). For example, after step S760, an opening 441a is formed using photolithography and etching. The opening 441a exposes the gate insulating layer 440 serving as the sidewall of the opening 441a and a part of the surface of the scanning signal line 129a.

Step S770 is a step of depositing the conductive layer 444 on the oxide semiconductor layer 442, on a part of the surface of the scanning signal line 129a, on the sidewall of the opening 441a and on a part of the gate insulating layer 440, so as to be in contact with the oxide semiconductor layer 442, a part of the surface of the scanning signal line 129a, the sidewall of the opening 441a, and a part of the gate insulating layer 440, using sputtering. For example, the conductive layer 444 can be formed using a material similar to that of the conductive layer 144.

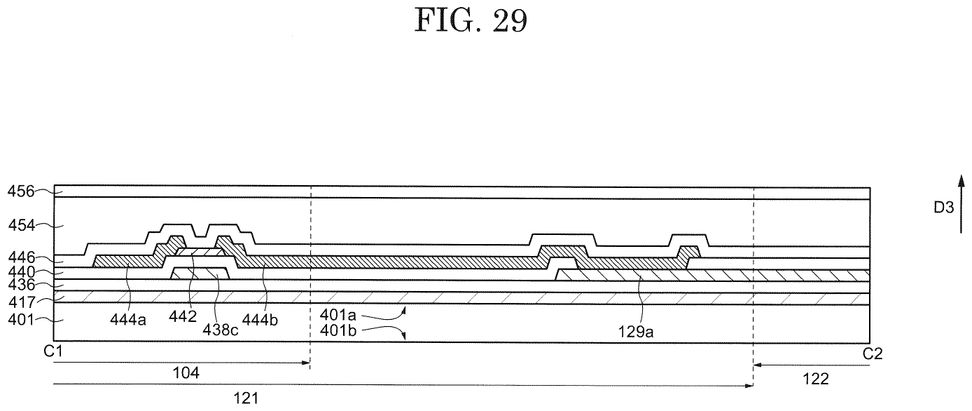

Step S780 is a step of processing the conductive layer 444 deposited in step S770 using photolithography and etching to form the source electrode, the drain electrode, and the wiring (see FIG. 25 and FIG. 29). The conductive layer 444 functions as the source electrode, drain electrode, or wiring. For example, the conductive layer 444 shown in FIG. 29 is the source electrode 444a and the drain electrode 444b.

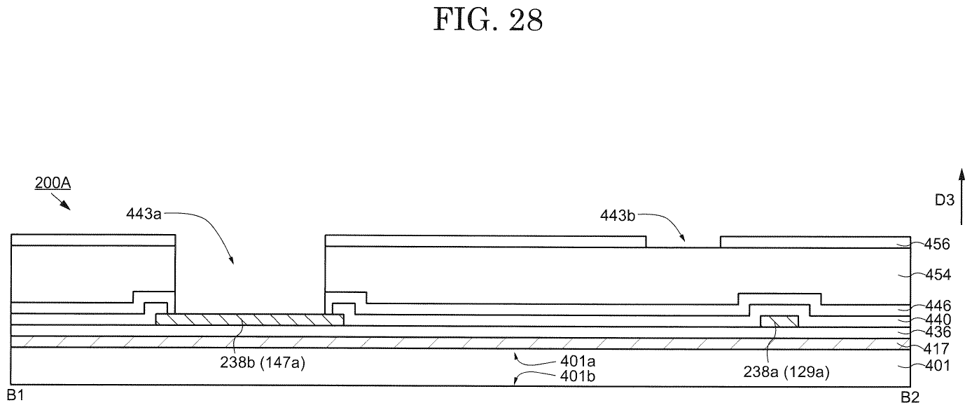

Step S790 is a step of depositing the insulating layer 446 on the conductive layer 444, on a part of the oxide semiconductor layer 442, and on a part of the gate insulating layer 440 to be in contact with the conductive layer 444, a part of the oxide semiconductor layer 442, and a part of the gate insulating layer 440 using CVD, depositing the insulating layer 454 on the insulating layer 446 to be in contact with the insulating layer 446, and depositing the insulating layer 456 on the insulating layer 454 to be in contact with the insulating layer 454 (see FIG. 25, FIG. 28, and FIG. 29). For example, the insulating layer 446 can be formed using a material similar to that of the gate insulating layer 440. The insulating layer 454 can be formed using a material similar to that of the insulating layer 380. Similar to the insulating layer 380, the insulating layer 454 can planarize unevenness due to the transistor 484 and the insulating layer 446. The insulating layer 456 can be formed using a material similar to that of the insulating layer 117. Similar to the insulating layer 117, the insulating layer 456 can prevent impurities from the outside (for example, moisture or sodium (Na)) from diffusing into the layers below the insulating layer 456.

Step S800 is a step of forming openings 443a and 443b using photolithography and etching. The opening 443a exposes the insulating layers 446, 454, and 456 serving as sidewalls of the opening 443a, and a part of the surface of the conductive layer 238b. The opening 443b exposes the insulating layer 456 serving as a sidewall of the opening 443b and a part of the surface of the insulating layer 454 (see FIG. 25 and FIG. 28).

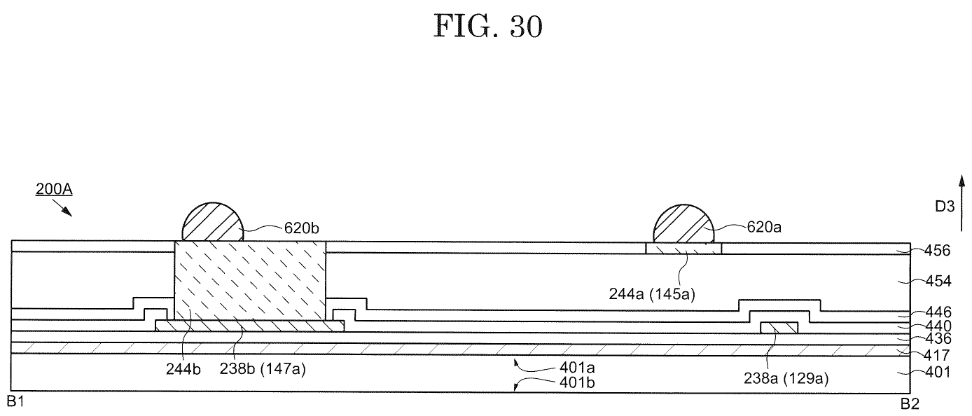

Step S810 is a step of forming a conductive layer. Specifically, this is a step of depositing a conductive film to be in contact with the insulating layers 446, 454, and 456 serving as sidewalls of the opening 443a, a part of the surface of the conductive layer 238b, the insulating layer 456 serving as a sidewall of the opening 443b, and a part of a part of the surface of the insulating layer 454 (see FIG. 25 and FIG. 30). For example, similar to step S340, the conductive film is deposited on the insulating layer and the conductive layer using sputtering and ECP. For example, the deposited conductive layer is polished using CMP and planarized until the surface of the insulating layer 456 is exposed. As a result, the first connecting conductive layers 244a and 244b can be formed. For example, the first connecting conductive layers 244a and 244b shown in FIG. 30 contain the conductive film, the first connecting conductive layer 244a functions as the ground wiring 145a, and the first connecting conductive layer 244b is electrically connected to the conductive layer 238b and functions as the driving potential line 147a. Although not shown, the first connecting conductive layers 244c and 244d are formed similar to the first connecting conductive layers 244a and 244b. The first connecting conductive layer 244c (see FIG. 3) is electrically connected to the conductive layer 238a and functions as the scanning signal line 129. The first connecting conductive layer 244d (see FIG. 3) functions as the data signal line 131.

A material similar to that of the conductive film deposited in step S340 can be used for the conductive film deposited in step S810. For example, a conductive layer composed of manganese and copper can be used as the conductive film. As a result, the display device 20 can suppress the diffusion of copper into the insulating layer in contact with the first connecting conductive layer 244, absorb hydrogen discharged from the insulating layer in contact with the first connecting conductive layer, and suppress deterioration in the electrical characteristics of the transistor 484. In addition, since the first connecting conductive layer 244 is formed using ECP, the first connecting conductive layer 244 can be formed thicker than the films and layers formed using sputtering or CVD. Therefore, the resistance values of the data signal line 131 (the first connecting conductive layer 244d) and the ground wiring 145a (the first connecting conductive layer 244a) formed using the first connecting conductive layer 244 can be made even smaller than the resistance values of wiring formed using a material with a higher specific resistance than copper. As a result, compared to the wiring formed using the material with a higher specific resistance than copper, the time constant of the signal supplied to the data signal line 131 is improved, and the charge supply amount of the potential supplied to the ground wiring 145a increases.

As described above, the backplane 200A is formed.

Steps S820 to S850 are similar to steps S450 to S500. Therefore, the description of steps S820 to S850 will be omitted here.

As described above, the method for manufacturing the display device 20 can electrically connect the pixel IC chip 181 (the first surface 101a of the array substrate 100) and the backplane 200A. As a result, the pixel IC chip 181 including the light-emitting diode 300 and the first transistor 184a to the third transistor 184c is electrically connected to the data signal line 131, the scanning signal line 129, the ground wiring 145, and the driving potential line 147 included in the backplane 200A.

The method for manufacturing the display device 20 including the configuration as described above has the same effects as the method for manufacturing the display device 10. In addition, since the method for manufacturing the display device 20 includes forming the scanning signal line driving circuit 104 in the peripheral region 121, the number of components mounted on the display device 20 can be reduced compared to the case where the IC chip including the scanning signal line driving circuit is mounted on the display device 20. As a result, the method for manufacturing the display device 20 can reduce the manufacturing cost.

Furthermore, in the transistor 484 included in the backplane 200A, the second substrate 401 side, the second substrate 401 side and the third direction D3 side can be covered with insulating layers 471 and 456 using AlOₓ. As a result, for example, impurities (for example, moisture or sodium (Na)) can be prevented from diffusing into the transistor 484. As a result, the method for manufacturing the display device 20 can suppress deterioration in the electrical characteristics of the transistor 484.

### 2-4. Example of Protection Circuit 460

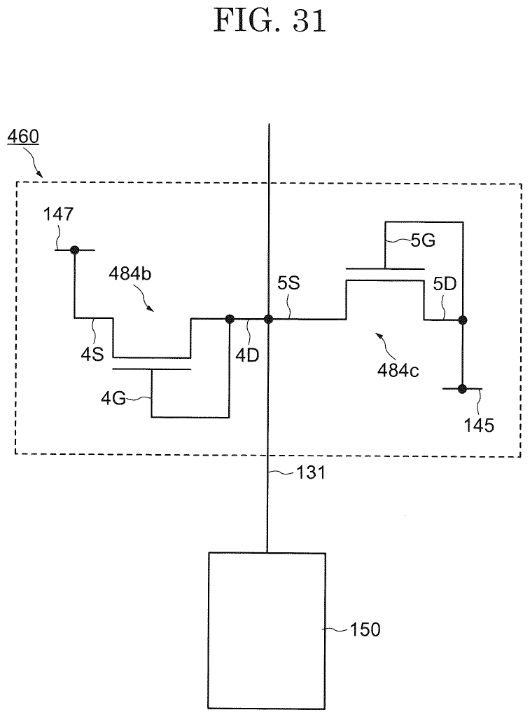

An example of the protection circuit 460 will be described with reference to FIG. 31. FIG. 31 is a plan view showing an example of the protection circuit 460. Configurations that are the same as or similar to those in FIG. 1 to FIG. 30 will be described as necessary.

The protection circuit 460 is electrically connected to the terminal 150 and the data signal line 131 connected to the terminal 150. The protection circuit 460 includes transistors 484b and 484 c, and the conduction state of the transistors 484b and 484c is controlled by the signal supplied to the signal line or wiring electrically connected to the protection circuit 460. The transistor 484b includes a gate electrode 4G, a source electrode 4S, and a drain electrode 4D. The transistor 484c includes a gate electrode 5G, a source electrode 5S, and a drain electrode 5D. The source electrode 4S is electrically connected to the driving potential line 147, and the drain electrode 4D is electrically connected to the gate electrode 4G, the data signal line 131, and the source electrode 5S. The drain electrode 5D is electrically connected to the gate electrode 5G and the ground wiring 145.

The drain electrode 4D is electrically connected to the gate electrode 4G and the data signal line 131. Therefore, when the potential supplied to the data signal line 131 is greater than the potential supplied to the driving potential line 147, the transistor 484b becomes conductive and functions as a protection circuit. That is, when an overvoltage is supplied to the data signal line 131 via the terminal 150, current can flow from the drain electrode 4D to the driving potential line 147 via the transistor 484b. As a result, the transistor 484b can suppress the application of overvoltage and the supply of overcurrent to the data signal line 131.

In addition, the drain electrode 5D is electrically connected to the gate electrode 5G and the ground wiring 145. Therefore, when the potential supplied to the source electrode 5S is smaller than the potential supplied to the ground wiring 145, the transistor 484c becomes conductive and functions as a protection circuit. That is, when an overvoltage is supplied to the data signal line 131 via the terminal 150, current can flow from the ground wiring 145 to the source electrode 5S via the transistor 484c. As a result, the transistor 484c can suppress the application of overvoltage and the supply of overcurrent to the data signal line 131.

Similar to the transistor 484a and the plurality of transistors 184, the transistors 484b and 484c include the oxide semiconductor layer 442 and are formed on the second substrate 401. As a result, the leakage current and off-current of the transistors 484b and 484c are smaller than the leakage current and off-current of the transistor containing amorphous silicon or polysilicon. Therefore, since the leakage current and off-current of the protection circuit 460 are small, the application of overvoltage and the supply of overcurrent to the data signal line 131 can be efficiently suppressed. In addition, the protection circuit 460 can suppress deterioration in electrical characteristics caused by the leakage current and off-current. Furthermore, the temperature characteristics of the off-current of the transistor formed using the oxide semiconductor layer are superior to the temperature characteristics of the off-current of the transistor formed using amorphous silicon or polysilicon. Therefore, since the display device 20 includes the protection circuit using the transistor with excellent temperature characteristics, a decrease in long-term reliability can be suppressed.

The embodiments or a part of the embodiments described above as the embodiment of the present invention can be appropriately combined and implemented as long as no contradiction is caused.

Furthermore, it is understood that, even if the effect is different from those provided by each of the above-described embodiments, the effect obvious from the description in the specification or easily predicted by persons ordinarily skilled in the art is apparently derived from the present invention.

What is claimed is:

1. A display device comprising:
a first substrate;
a light-emitting diode including a gallium nitride layer arranged on a first surface of the first substrate;
a first transistor arranged on the light-emitting diode and electrically connected to the light-emitting diode;
a second substrate facing the first substrate;
a data signal line arranged on the second substrate;
a ground wiring arranged on the second substrate;
a first conductor arranged on the data signal line and electrically connecting the data signal line to the first transistor; and
a second conductor arranged on the ground wiring and electrically connecting the ground wiring to the light-emitting diode.

2. The display device according to claim 1, wherein the first substrate is a sapphire substrate or an amorphous glass substrate, and the second substrate is an amorphous glass substrate.

3. The display device according to claim 1, wherein the first transistor includes an oxide semiconductor layer.

4. The display device according to claim 1, wherein the data signal line is arranged in the same layer as the ground wiring.

5. The display device according to claim 4, further comprising:
a second transistor; and
a third transistor,
wherein the second transistor is electrically connected to the data signal line and the first transistor, and
the third transistor is electrically connected to the first transistor and the ground wiring and connected in parallel to the light-emitting diode.

6. The display device according to claim 4, further comprising:
a scanning signal line; and
a third conductor,
wherein the scanning signal line is arranged between the second substrate and the same layer, and electrically connected to the first transistor via the third conductor.

7. The display device according to claim 6, wherein the data signal line, the ground wiring, and the scanning signal line include conductive layers containing copper and manganese.

8. The display device according to claim 3, further comprising a first planarization film,
wherein the first planarization film is arranged between the light-emitting diode and the first transistor.

9. The display device according to claim 8, further comprising:
a first insulating layer;
a second insulating layer; and
a third insulating layer,
wherein the first insulating layer is arranged so as to cover the light-emitting diode,
the second insulating layer is arranged so as to be in contact with the first planarization film,
the third insulating layer is arranged on the first transistor, and
the first insulating layer, the second insulating layer, and the third insulating layer contain aluminum oxide.

10. The display device according to claim 9, wherein the first transistor includes a source electrode, a gate electrode, and a drain electrode,
wherein the source electrode and the drain electrode are arranged on the same layer, spaced apart from each other, and arranged on top of the oxide semiconductor layer, and
the source electrode and the drain electrode include a conductive layer containing titanium.

11. The display device according to claim 1, further comprising a second planarization film,
wherein the second planarization film is arranged on the first transistor and includes a first opening and a second opening,
the first conductor is arranged in the first opening and electrically connected to the first transistor, and
the second conductor is arranged in the second opening and electrically connected to the light-emitting diode.

12. The display device according to claim 1, further comprising a color conversion layer configured to convert a color of light emitted by the light-emitting diode to a color different from the color of light emitted by the light-emitting diode,
wherein the first substrate includes a second surface opposite the first surface, and
the color conversion layer is arranged on the second surface.

13. The display device according to claim 6, further comprising a driver IC,
wherein the driver IC is electrically connected to the data signal line, the ground wiring, and the scanning signal line, and configured to be able to control the light-emitting diode.

14. The display device according to claim 6, further comprising a drive circuit arranged on the second substrate,
wherein the drive circuit connected to the scanning signal line.

15. The display device according to claim 14, wherein the drive circuit includes a plurality of transistors different from the first transistor, and
the plurality of transistors includes an oxide semiconductor layer.

16. The display device according to claim 15, further comprising a protection circuit arranged on the second substrate,
wherein the protection circuit is electrically connected to the data signal line and includes a transistor different from the first transistor and the plurality of transistors, and
the transistor different from the first transistor and the plurality of transistors includes an oxide semiconductor layer.
